(19) United States
(12) Patent Application Publication
(10) Pub. No.: US 2025/0365919 A1
(43) Pub. Date: Nov. 27, 2025

(54) SUBSTRATE ISOLATION IN A THREE DIMENSIONAL (3D) MEMORY ARRAY

(71) Applicant: Micron Technology, Inc., Boise, ID (US)

(72) Inventors: Eyob Tarekegn, Boise, ID (US); Kolya Yastrebenetsky, Boise, ID (US); Alyssa N. Scarbrough, Boise, ID (US); Collin Howder, Meridian, ID (US); David A. Daycock, Boise, ID (US)

(21) Appl. No.: 19/183,069

(22) Filed: Apr. 18, 2025

Related U.S. Application Data
(60) Provisional application No. 63/650,483, filed on May 22, 2024.

(51) Int. Cl. H10B 12/00

(52) U.S. Cl. CPC H10B 12/02; H10B 12/482

(57) ABSTRACT

Systems, methods, and apparatus are provided for substrate isolation in a three-dimensional (3D) memory array. The 3D array of vertically stacked memory cells formed on a substrate, the vertically stacked memory cells having horizontally oriented access devices and storage nodes can include a first portion of a digit line liner formed on the substrate, a second portion of the digit line liner formed on the substrate, and a dielectric material having a portion formed between the first portion of the digit line liner and the second portion of the digit line liner and the substrate.

### PRIORITY INFORMATION

This application claims the benefit of U.S. Provisional Application No. 63/650,483, filed on May 22, 2024, the contents of which are incorporated herein by reference.

### TECHNICAL FIELD

The present disclosure relates generally to memory devices, and more particularly, to substrate isolation in a 3D memory array.

### BACKGROUND

Memory is often implemented in electronic systems, such as computers, cell phones, hand-held devices, etc. There are many different types of memory, including volatile and non-volatile memory. Volatile memory may require power to maintain its data and may include random-access memory (RAM), dynamic random-access memory (DRAM), static random-access memory (SRAM), and synchronous dynamic random-access memory (SDRAM). Non-volatile memory may provide persistent data by retaining stored data when not powered and may include NAND flash memory, NOR flash memory, nitride read only memory (NROM), phase-change memory (e.g., phase-change random access memory), resistive memory (e.g., resistive random-access memory), cross-point memory, ferroelectric random-access memory (FeRAM), or the like.

As design rules shrink, less semiconductor space is available to fabricate memory, including DRAM arrays. A respective memory cell for DRAM may include an access device, e.g., transistor, having a first and a second source/drain region separated by a channel region. A gate may oppose the channel region and be separated therefrom by a gate dielectric. An access line, such as a word line, is electrically connected to the gate of the DRAM memory cell. A DRAM memory cell can include a storage node, such as a capacitor cell, coupled by the access device to a sense line, such as a digit line. The access device can be activated (e.g., to select the cell) by an access line coupled to the access device. The capacitor can store a charge corresponding to a data value of a respective memory cell (e.g., a logic “1” or “0”).

### BRIEF DESCRIPTION OF THE DRAWINGS

FIG. 1A is a schematic illustration of an array of memory cells in a vertical three dimensional (3D) memory in accordance with a number of embodiments of the present disclosure.

FIG. 1B is a perspective view illustrating a portion of a horizontal access devices in vertical three dimensional (3D) memory in accordance with a number of embodiments of the present disclosure.

FIG. 2 illustrates a portion of a horizontal access device in vertical three dimensional (3D) memory in accordance with a number of embodiments of the present disclosure.

FIG. 3 is a schematic illustration of a vertical three dimensional memory in accordance with a number of embodiments of the present disclosure.

FIG. 4 is a perspective view illustrating horizontal access devices in accordance with a number of embodiments of the present disclosure.

FIG. 5 is a cross-sectional view of a vertical stack in vertical three dimensional (3D) memory in accordance with a number of embodiments of the present disclosure.

FIGS. 6A to 6B illustrate an example method, at one stage of a semiconductor fabrication process, for substrate isolation in vertical three dimensional (3D) memory, in accordance with a number of embodiments of the present disclosure.

FIGS. 7A to 7D illustrate an example method, at another stage of a semiconductor fabrication process, for substrate isolation in vertical three dimensional (3D) memory, in accordance with a number of embodiments of the present disclosure.

FIGS. 8A to 8B illustrate an example method, at another stage of a semiconductor fabrication process, for substrate isolation in vertical three dimensional (3D) memory, in accordance with a number of embodiments of the present disclosure.

FIGS. 9A to 9F illustrate an example method, at one stage of a semiconductor fabrication process, for isolating substrate in three dimensional (3D) arrays of vertically stacked memory cells, having horizontally oriented access devices and storage nodes, in accordance with a number of embodiments of the present disclosure.

FIGS. 10A to 10E illustrate an example method, at one stage of a semiconductor fabrication process, for isolating substrate in three dimensional (3D) arrays of vertically stacked memory cells, having horizontally oriented access devices and storage nodes, in accordance with a number of embodiments of the present disclosure.

FIG. 11 illustrates an example method, at another stage of a semiconductor fabrication process, for substrate isolation in vertical three dimensional (3D) memory, in accordance with a number of embodiments of the present disclosure.

FIGS. 12A to 12C illustrate an example method, at another stage of a semiconductor fabrication process, for substrate isolation in vertical three-dimensional (3D) memory, in accordance with a number of embodiments of the present disclosure.

FIG. 13 is a block diagram of an apparatus in the form of a computing system including a memory device in accordance with a number of embodiments of the present disclosure.

### DETAILED DESCRIPTION

Embodiments of the present disclosure describe substrate isolation in a three dimensional (3D) memory array. The 3D memory array of vertically stacked memory cells formed on a substrate, the vertically stacked memory cells having horizontally oriented access devices and storage nodes. The 3D memory array can include a first portion of a digit line liner formed on the 3D memory array of vertically stacked memory cells, a second portion of the digit line liner formed on the substrate, and a dielectric material having a portion formed between the first portion of the digit line liner and the second portion of the digit line liner and the substrate.

In some previous approaches, 3D memory arrays of vertically stacked memory cells and digit line liners are connected to a substrate. Isolating a 3D array of vertically stacked memory cells and a digit line liner from a substrate, as disclosed herein, can avoid shorting of digit line liners. Further, using a doped layer removal for isolating the 3D array of vertically stacked memory cells and the digit line liner from the substrate can prevent the need for trench depth alignment with the first layer of a vertical stack and enables trenches (e.g., openings) to be etched at the same time.

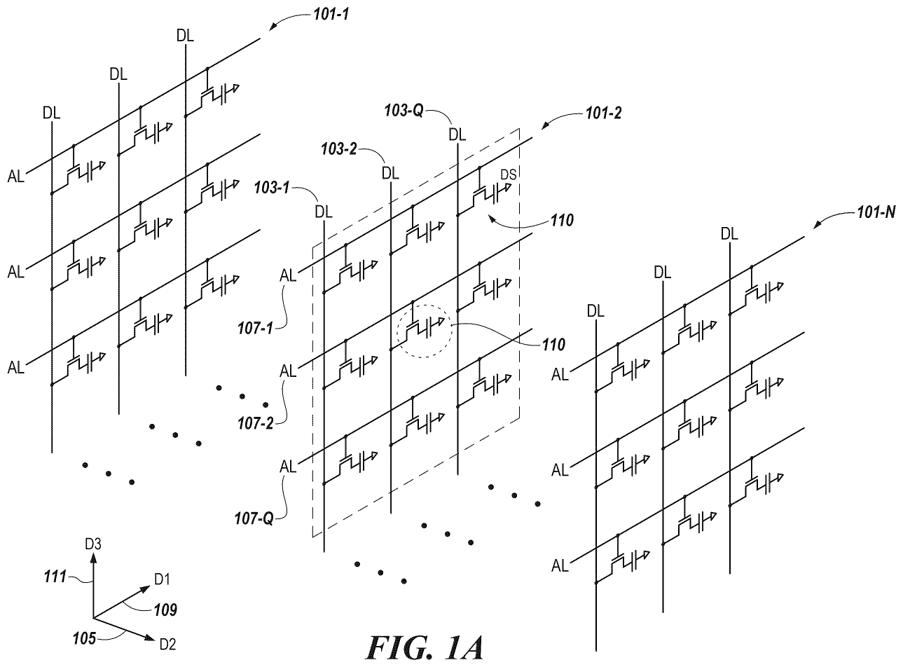

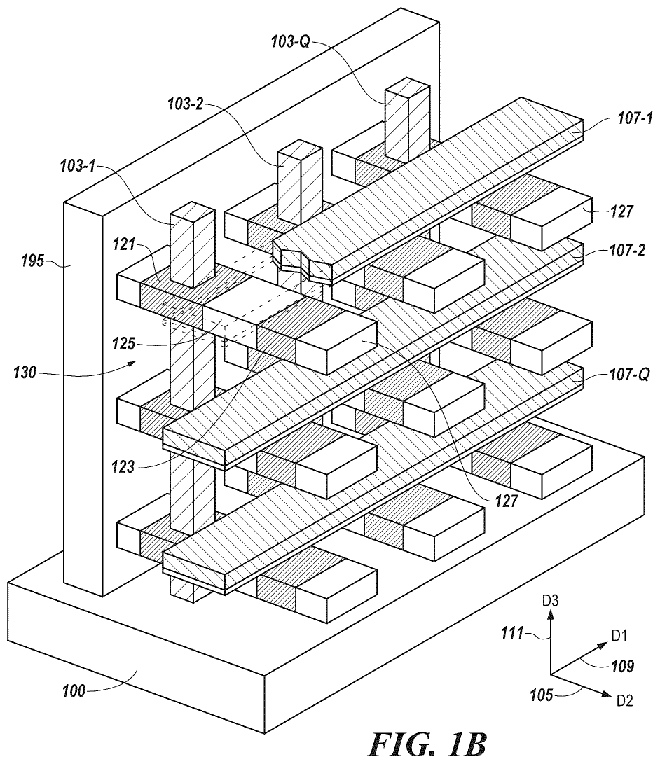

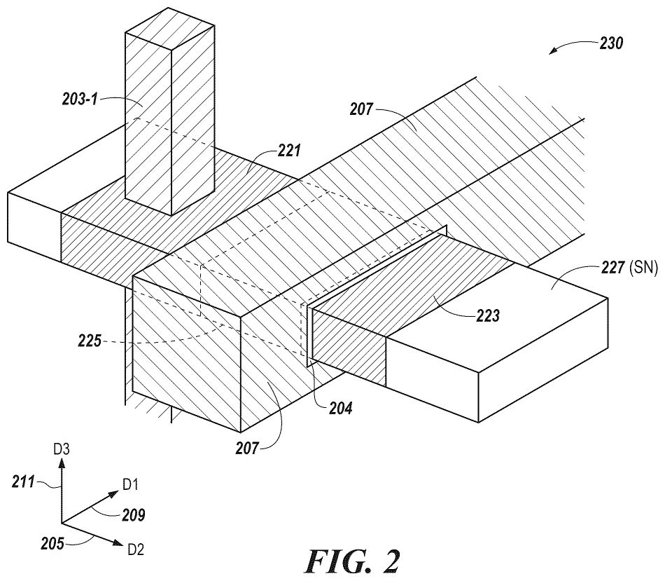

The figures herein follow a numbering convention in which the first digit or digits correspond to the figure number of the drawing and the remaining digits identify an element or component in the drawing. Similar elements or components between different figures may be identified by the use of similar digits. For example, reference numeral 107 may reference element “07” in FIG. 1A, and a similar element may be referenced as 207 in FIG. 2. Multiple analogous elements within one figure may be referenced with a reference numeral followed by a hyphen and another numeral or a letter. For example, 107-1 may reference element 107-1 in FIG. 1A and 107-2 may reference element 107-2, which may be analogous to element 107-1. Such analogous elements may be generally referenced without the hyphen and extra numeral or letter. For example, elements 107-1 and 107-2 or other analogous elements may be generally referenced as 107.

FIG. 1A is a schematic illustration of an array of memory cells in a vertical three dimensional (3D) memory in accordance with a number of embodiments of the present disclosure. FIG. 1A illustrates that a cell array may have a plurality of sub cell arrays 101-1, 101-2, . . . , 101-N. The sub cell arrays 101-1, 101-2, . . . , 101-N may be arranged along a second direction (D2) 105. Each of the sub cell arrays, e.g., sub cell array 101-2, may include a plurality of access lines 107-1, 107-2, . . . , 107-Q (which also may be referred to as word lines). Also, each of the sub cell arrays, e.g., sub cell array 101-2, may include a plurality of digit lines 103-1, 103-2, . . . , 103-Q (which also may be referred to as bit lines, data lines, or sense lines). In FIG. 1A, the access lines 107-1, 107-2, . . . , 107-Q are illustrated extending in a first direction (D1) 109 and the digit lines 103-1, 103-2, . . . , 103-Q are illustrated extending in a third direction (D3) 111. According to embodiments, the first direction (D1) 109 and the second direction (D2) 105 may be considered in a horizontal (“X-Y”) plane. The third direction (D3) 111 may be considered in a vertical (“Z”) plane. Hence, according to embodiments described herein, the digit lines 103-1, 103-2, . . . , 103-Q are extending in a vertical direction, e.g., third direction (D3) 111.

A memory cell, e.g., 110, may include an access device, e.g., access transistor, and a storage node located at an intersection of each access line 107-1, 107-2, . . . , 107-Q and each digit line 103-1, 103-2, . . . , 103-Q. Memory cells may be written to, or read from, using the access lines 107-1, 107-2, . . . , 107-Q and digit lines 103-1, 103-2, . . . , 103-Q. The access lines 107-1, 107-2, . . . , 107-Q may conductively interconnect memory cells along horizontal rows of each sub cell array 101-1, 101-2, . . . , 101-N, and the digit lines 103-1, 103-2, . . . , 103-Q may conductively interconnect memory cells along vertical columns of each sub cell array 101-1, 101-2, . . . , 101-N. One memory cell, e.g., 110, may be located between one access line, e.g., 107-2, and one digit line, e.g., 103-2. Each memory cell 110 may be uniquely addressed through a combination of an access line 107-1, 107-2, . . . , 107-Q and a digit line 103-1, 103-2, . . . , 103-Q.

The access lines 107-1, 107-2, . . . , 107-Q may be or include conducting patterns (e.g., metal lines) disposed on and spaced apart from a substrate. The access lines 107-1, 107-2, . . . , 107-Q may extend in a first direction (D1) 109. The access lines 107-1, 107-2, . . . , 107-Q in one sub cell array, e.g., 101-2, may be spaced apart from each other in a vertical direction, e.g., in a third direction (D3) 111.

The digit lines 103-1, 103-2, . . . , 103-Q may be or include conductive patterns (e.g., metal lines) extending in a vertical direction with respect to the substrate, e.g., in a third direction (D3) 111. The digit lines 103-1, 103-2, . . . , 103-Q in one sub cell array, e.g., 101-2, may be spaced apart from each other in the first direction (D1) 109.

A gate of a memory cell, e.g., memory cell 110, may be connected to an access line, e.g., 107-2, and a first conductive node, e.g., a first source/drain region, of an access device, e.g., transistor, of the memory cell 110 may be connected to a digit line, e.g., 103-2. Each of the memory cells, e.g., memory cell 110, may be connected to a storage node, e.g., capacitor. A second conductive node, e.g., second source/drain region, of the access device, e.g., transistor, of the memory cell 110 may be connected to the storage node, e.g., capacitor. While first and second source/drain region references are used herein to denote two separate and distinct source/drain regions, it is not intended that the source/drain region referred to as the “first” and/or “second” source/drain regions have some unique meaning. It is intended only that one of the source/drain regions is connected to a digit line, e.g., 103-2, and the other may be connected to a storage node.

FIG. 1B illustrates a perspective view showing a three dimensional (3D) semiconductor memory device, e.g., a portion of a sub cell array 101-2 shown in FIG. 1A as a vertically oriented stack of memory cells in an array, according to some embodiments of the present disclosure.

As shown in FIG. 1B, a substrate 100 may have formed thereon one of the plurality of sub cell arrays, e.g., 101-2, described in connection with FIG. 1A. For example, the substrate 100 may be or include a silicon substrate, a germanium substrate, or a silicon-germanium substrate, etc. Embodiments, however, are not limited to these examples.

As shown in the example embodiment of FIG. 1B, the substrate 100 may have fabricated thereon a vertically oriented stack of memory cells, e.g., memory cell 110 in FIG. 1A, extending in a vertical direction, e.g., third direction (D3) 111.

The plurality of discrete components to the laterally oriented access devices 130, e.g., transistors, may include a first source/drain region 121 and a second source/drain region 123 separated by a channel region 125, extending laterally in the second direction (D2) 105, and formed in a body of the access devices. In some embodiments, the channel region 125 may include silicon, germanium, silicon-germanium, and/or indium gallium zinc oxide (IGZO). In some embodiments, the first and the second source/drain regions, 121 and 123, can include an n-type dopant region formed in a p-type doped body to the access device to form an n-type conductivity transistor. In some embodiments, the first and the second source/drain regions, 121 and 123, may include a p-type dopant formed within an n-type doped body to the access device to form a p-type conductivity transistor. By way of example, and not by way of limitation, the n-type dopant may include phosphorous (P) atoms and the p-type dopant may include atoms of boron (B) formed in an oppositely doped body region of polysilicon semiconductor material. Embodiments, however, are not limited to these examples.

The storage node 127, e.g., capacitor, may be connected to one respective end of the access device. As shown in FIG. 1B, the storage node 127, e.g., capacitor, may be connected to the second source/drain region 123 of the access device. The storage node may be or include memory elements capable of storing data. Each of the storage nodes may be a memory element using one of a capacitor, a magnetic tunnel junction pattern, and/or a variable resistance body which includes a phase change material, etc. Embodiments, however, are not limited to these examples. In some embodiments, the storage node associated with each access device of a unit cell, e.g., memory cell 110 in FIG. 1A, may similarly extend in the second direction (D2) 105, analogous to second direction (D2) 105 shown in FIG. 1A.

As shown in FIG. 1B a plurality of horizontally oriented access lines 107-1, 107-2, . . . , 107-Q extend in the first direction (D1) 109, analogous to the first direction (D1) 109 in FIG. 1A. The plurality of horizontally oriented access lines 107-1, 107-2, . . . , 107-Q may be analogous to the access lines 107-1, 107-2, . . . , 107-Q shown in FIG. 1A. The plurality of horizontally oriented access lines 107-1, 107-2, . . . , 107-Q may be arranged, e.g., “stacked”, along the third direction (D3) 111. The plurality of horizontally oriented access lines 107-1, 107-2, . . . , 107-Q may include a conductive material. For example, the conductive material may include one or more of a doped semiconductor, e.g., doped silicon, doped germanium, etc., a conductive metal nitride, e.g., titanium nitride, tantalum nitride, etc., a metal, e.g., tungsten (W), titanium (Ti), tantalum (Ta), ruthenium (Ru), cobalt (Co), molybdenum (Mo), etc., and/or a metal-semiconductor compound, e.g., tungsten silicide, cobalt silicide, titanium silicide, etc. Embodiments, however, are not limited to these examples.

The horizontally oriented memory cells, e.g., memory cell 110 in FIG. 1A, may be spaced apart from one another horizontally in the first direction (D1) 109. The plurality of discrete components to the horizontally oriented access devices 130, e.g., first source/drain region 121 and second source/drain region 123 separated by a channel region 125, can extend laterally in the second direction (D2) 105, and the plurality of horizontally oriented access lines 107-1, 107-2, . . . , 107-Q can extend laterally in the first direction (D1) 109. For example, the plurality of horizontally oriented access lines 107-1, 107-2, . . . , 107-Q, extending in the first direction (D1) 109, may be formed on a top surface opposing and electrically coupled to the channel regions 125, separated therefrom by a gate dielectric, and orthogonal to horizontally oriented access devices 130, e.g., transistors, extending in laterally in the second direction (D2) 105.

As shown in the example embodiment of FIG. 1B, the digit lines, 103-1, 103-2, . . . , 103-Q, extend in a vertical direction with respect to the substrate 100, e.g., in a third direction (D3) 111. Further, as shown in FIG. 1B, the digit lines, 103-1, 103-2, . . . , 103-Q, in one sub cell array, e.g., sub cell array 101-2 in FIG. 1A, may be spaced apart from each other in the first direction (D1) 109. The digit lines, 103-1, 103-2, . . . , 103-Q, may be provided, extending vertically relative to the substrate 100 in the third direction (D3) 111 in vertical alignment with source/drain regions to serve as first source/drain regions 121 or, as shown, be vertically adjacent first source/drain regions 121 for each of the horizontally oriented access devices 130, e.g., transistors, extending laterally in the second direction (D2) 105. Each of the digit lines, 103-1, 103-2, . . . , 103-Q, may vertically extend, in the third direction (D3) 111, on sidewalls adjacent first source/drain regions 121 of respective ones of the plurality of horizontally oriented access devices 130, e.g., transistors, that are vertically stacked. In some embodiments, the plurality of vertically oriented digit lines 103-1, 103-2, . . . , 103-Q, extending in the third direction (D3) 111, may be connected to side surfaces of the first source/drain regions 121 directly and/or through additional contacts including metal silicides.

For example, a first one of the vertically extending digit lines, e.g., 103-1, may be adjacent a sidewall of a first source/drain region 121 to a first one of the horizontally oriented access devices 130, a sidewall of a first source/drain region 121 of a first one of the horizontally oriented access devices 130, and a sidewall of a first source/drain region 121 a first one of the horizontally oriented access devices 130, etc. Similarly, a second one of the vertically extending digit lines, e.g., 103-2, may be adjacent a sidewall to a first source/drain region 121 of a second one of the horizontally oriented access devices 130, spaced apart from the first one of horizontally oriented access devices 130 in the first direction (D1) 109. And the second one of the vertically extending digit lines, e.g., 103-2, may be adjacent a sidewall of a first source/drain region 121 of a second one of the laterally oriented access devices 130, and a sidewall of a first source/drain region 121 of a second one of the horizontally oriented access devices 130, etc.

The vertically extending digit lines, 103-1, 103-2, . . . , 103-Q, may include a conductive material, such as, for example, one of a doped semiconductor material, a conductive metal nitride, metal, and/or a metal-semiconductor compound. The digit lines, 103-1, 103-2, . . . , 103-Q, may correspond to digit lines (DL) described in connection with FIG. 1A.

As shown in the example embodiment of FIG. 1B, a conductive body contact may be formed extending in the first direction (D1) 109 along an end surface of the horizontally oriented access devices 130 above the substrate 100. The body contact 195 may be connected to a body e.g., body region, of the horizontally oriented access devices 130, e.g., transistors, in each memory cell, e.g., memory cell 110 in FIG. 1A. The body contact may include a conductive material such as, for example, one of a doped semiconductor material, a conductive metal nitride, metal, and/or a metal-semiconductor compound.

Although not shown in FIG. 1B, an insulating material may fill other spaces in the vertically stacked array of memory cells. For example, the insulating material may include one or more of a silicon oxide material, a silicon nitride material, and/or a silicon oxynitride material, etc. Embodiments, however, are not limited to these examples.

FIG. 2 illustrates a portion of a horizontal access device in vertical three-dimensional (3D) memory in accordance with a number of embodiments of the present disclosure. FIG. 2 illustrates in more detail a unit cell, e.g., memory cell 110 in FIG. 1A, of the vertically stacked array of memory cells, e.g., within a sub cell array 101-2 in FIG. 1A, according to some embodiments of the present disclosure. As shown in FIG. 2, the first and the second source/drain regions, 221 and 223, may be impurity doped regions to the laterally oriented access devices 230, e.g., transistors. The first and the second source/drain regions may be separated by a channel 225 formed in a body of semiconductor material, e.g., body region of the horizontally oriented access devices 230, e.g., transistors. The first and the second source/drain regions, 221 and 223, may be formed from an n-type or p-type dopant doped in the body region. However, embodiments are not so limited.

For example, for an n-type conductivity transistor construction the body region of the laterally oriented access devices 230, e.g., transistors, may be formed of a low doped p-type (p-) semiconductor material. In one embodiment, the body region and the channel 225 separating the first and the second source/drain regions, 221 and 223, may include a low doped, p-type (e.g., low dopant concentration (p-)) polysilicon (Si) material consisting of boron (B) atoms as an impurity dopant to the polycrystalline silicon. The first and the second source/drain regions, 221 and 223, may also comprise a metal, and/or metal composite materials containing ruthenium (Ru), molybdenum (Mo), nickel (Ni), titanium (Ti), copper (Cu), a highly doped degenerate semiconductor material, and/or at least one of indium oxide (In2O3), or indium tin oxide (In2-xSnxO3), formed using an atomic layer deposition process, etc. Embodiments, however, are not limited to these examples. As used herein, a degenerate semiconductor material is intended to mean a semiconductor material, such as polysilicon, containing a high level of doping with significant interaction between dopants, e.g., phosphorus (P), boron (B), etc. Non-degenerate semiconductors, by contrast, contain moderate levels of doping, where the dopant atoms are well separated from each other in the semiconductor host lattice with negligible interaction.

In this example, the first and the second source/drain regions, 221 and 223, may include a high dopant concentration, n-type conductivity impurity (e.g., high dopant (n+)) doped in the first and the second source/drain regions, 221 and 223. In some embodiments, the high dopant, n-type conductivity first and second drain regions 221 and 223 may include a high concentration of phosphorus (P) atoms deposited therein. Embodiments, however, are not limited to this example. In other embodiments, the horizontally oriented access devices 230, e.g., transistors, may be of a p-type conductivity construction in which case the impurity, e.g., dopant, conductivity types would be reversed.

As shown in FIG. 2, the first and the second source/drain regions, 221 and 223, may be impurity doped regions to the laterally oriented access devices 230, e.g., transistors. The first and the second source/drain regions may be separated by a channel 225 formed in a body of semiconductor material, e.g., body region, of the horizontally oriented access devices 230, e.g., transistors. The first and the second source/drain regions, 221 and 223, may be formed from an n-type or p-type dopant doped in the body region. However, embodiments are not so limited.

The first source/drain region 221 may occupy an upper portion in the body of the laterally oriented access devices 230, e.g., transistors. For example, the first source/drain region 221 may have a bottom surface within the body of the horizontally oriented access device 230 which is located higher, vertically in the third direction (D3) 211, than a bottom surface of the body of the laterally, horizontally oriented access device 230. As such, the laterally, horizontally oriented access device 230 may have a body portion which is below the first source/drain region 221 and is in electrical contact with the body contact. Further, as shown in the example embodiment of FIG. 2, an access line, e.g., 207, analogous to the access lines 107-1, 107-2, . . . , 107-Q shown in FIGS. 1A and 1B, may be disposed on a top surface opposing and coupled to a channel region 225, separated therefrom by a gate dielectric 204. The gate dielectric material 204 may include, for example, a high-k dielectric material, a silicon oxide material, a silicon nitride material, a silicon oxynitride material, etc., or a combination thereof. Embodiments are not so limited. For example, in high-k dielectric material examples the gate dielectric material 204 may include one or more of hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, lead zinc niobite, etc.

As shown in the example embodiment of FIG. 2, a digit line, e.g., 203-1, analogous to the digit lines 103-1, 103-2, . . . , 103-Q in FIGS. 1A and 1B, may be vertically extending in the third direction (D3) 211 adjacent a sidewall of the first source/drain region 221 in the body to the horizontally oriented access devices 230, e.g., transistors horizontally conducting between the first and the second source/drain regions 221 and 223 along the second direction (D2) 205. In this embodiment, the vertically oriented digit line 203-1 is formed symmetrically, in vertical alignment, in electrical contact with the first source/drain region 221. The digit line 203-1 may be formed in contact with an insulator material such that there is no body contact within channel 225.

As shown in the example embodiment of FIG. 2, the digit line 203-1 may be formed symmetrically within the first source/drain region 221 such that the first source/drain region 221 surrounds the digit line 203-1 all around. The first source/drain region 221 may occupy an upper portion in the body of the laterally oriented access devices 230, e.g., transistors. For example, the first source/drain region 221 may have a bottom surface within the body of the horizontally oriented access device 230 which is located higher, vertically in the third direction (D3) 211, than a bottom surface of the body of the laterally, horizontally oriented access device 230. As such, the laterally, horizontally oriented transistor 230 may have a body portion which is below the first source/drain region 221 and is in contact with the body contact. An insulator material may fill the body contact such that the first source/drain region 221 may not be in electrical contact with channel 225. Further, as shown in the example embodiment of FIG. 2, an access line, e.g., 207, analogous to the access lines 107-1, 107-2, . . . , 107-Q shown in FIGS. 1A and 1B, may be disposed all around and coupled to a channel region 225, separated therefrom by a gate dielectric 204.

Although the digit line 203-1 is described above as being formed symmetrically within the first source/drain region 221 such that the first source/drain region 221 surrounds the digit line 203-1 all around, embodiments are not so limited. For instance, in some examples, the digit line 203-1 can be formed asymmetrically. In this embodiment, the vertically oriented digit line is formed asymmetrically adjacent in electrical contact with the first source/drain regions 221. The digit line may be formed asymmetrically to reserve room for a body contact in the channel region 225.

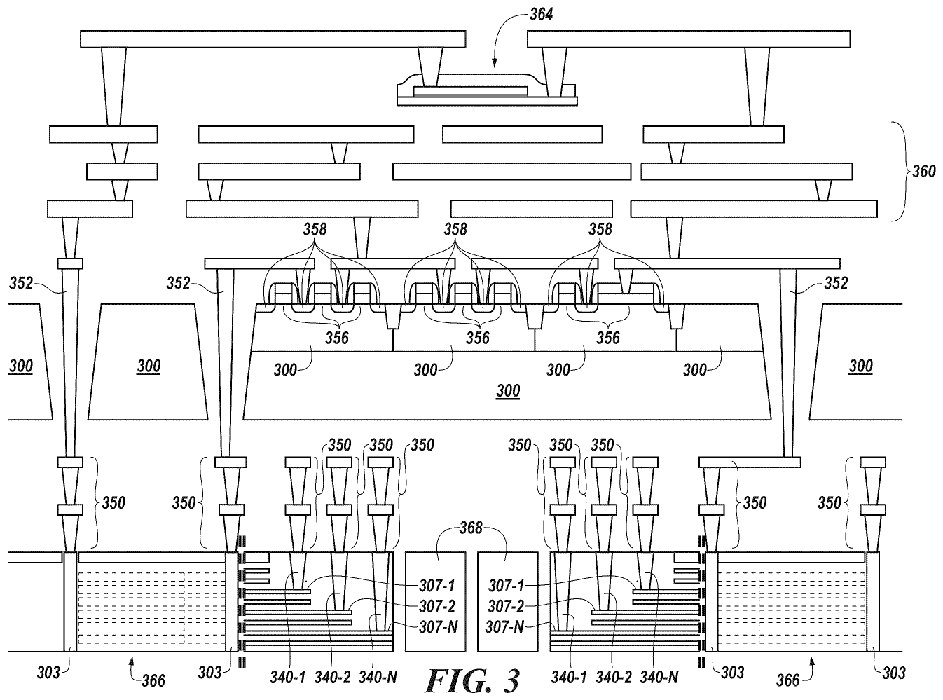

FIG. 3 is a schematic illustration of a vertical three dimensional (3D) memory in accordance with a number of embodiments of the present disclosure. FIG. 3 includes horizontally oriented access lines 307-1, 307-2, . . . , 307-N (individually or collectively referred to as horizontally access lines 307), access line contacts 340-1, 340-2, . . . , 340-N (individually or collectively referred to as access line contacts 340), and vertically oriented sense lines 303.

FIG. 3 illustrates different portions of the vertical 3D memory at different vertical heights of the vertical 3D memory. In the portion of the vertical 3D memory at the lowest vertical height shown in FIG. 3, FIG. 3 illustrates a staircase structure in a periphery of the vertical 3D memory that includes horizontally oriented access lines 307. As used herein, the term “periphery of the vertical 3D memory” refers to an area at an edge of the vertical 3D memory. For example, in FIG. 3, the periphery of the vertical 3D memory can refer to the portion of the vertical 3D memory that includes an area of a structure within the vertical 3D memory that is adjacent a vertical opening that separates a portion of the vertical 3D from a different portion of the vertical 3D memory. For example, the horizontally oriented access lines 307 are in a portion of the vertical 3D memory (e.g., the periphery) that is adjacent a vertical opening that separates this portion of the vertical 3D memory from vertical pillars 368.

FIG. 3 further illustrates access line contacts 340 coupled to the access lines 307. In some embodiments, the access line contacts 340 can be coupled to conductive lines 350. In some embodiments, conductive lines 350 can be coupled to a power source that can supply power to the access lines 307 through the access line contacts 340. Portions 366 of the vertical 3D memory can include dielectric materials and conductive materials and layers of silicon material.

At a portion of the vertical 3D memory array that is located at a higher vertical height than the previously described portion of the vertical 3D memory, FIG. 3 illustrates a plurality of transistors 356 formed on substrate materials 300. The substrate material 300 can be doped to from source/drain regions 358. Conductive lines 352 can be coupled to conductive lines 350 at a lower vertical height than conductive lines 352 and coupled to conductive lines 360 that are at a higher vertical height than conductive lines 352. Further, conductive lines 360 can be coupled to memory component 364.

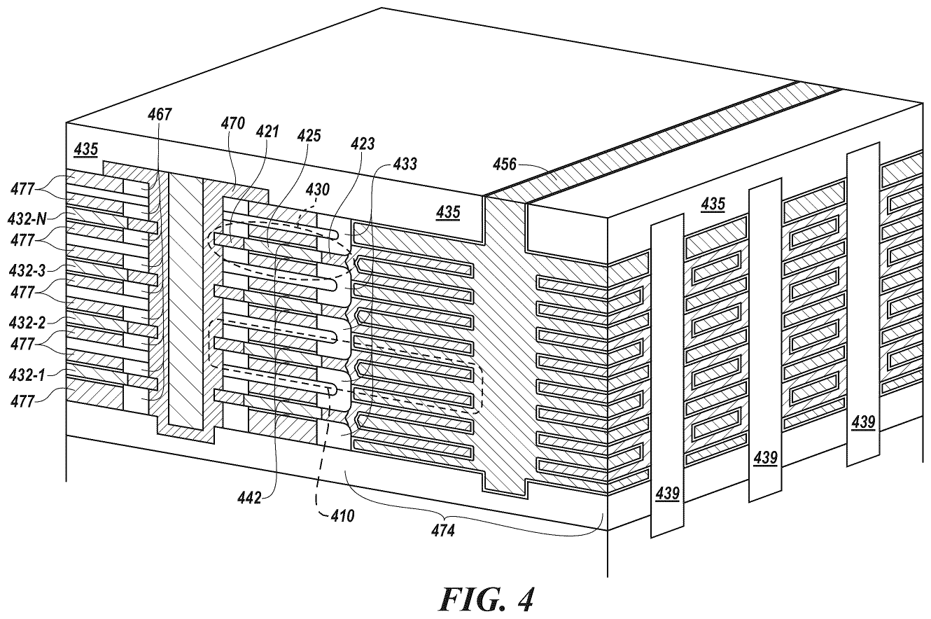

FIG. 4 is a perspective view of a three-dimensional (3D) dynamic random access memory (DRAM) array having horizontally oriented memory cells 410. The example embodiment of FIG. 4 is illustrating an array of 3D DRAM having horizontally oriented memory cells 410 combinable with multi-wafer logic in accordance with a number of embodiments of the present disclosure. The horizontally oriented memory cells 410 in the array comprise horizontally oriented access devices 430 having first source/drain regions 421 and second source/drain regions 423 separated by channel regions 425. Horizontally oriented access lines 477 form gates separated from the channel regions 425 by gate dielectric material 442. As shown in the example embodiment, horizontally oriented storage nodes 474 are electrically coupled to the second source/drain regions 423 of the horizontally oriented access devices 430. The horizontally oriented storage nodes 474 include a first electrode, e.g., bottom electrode, and a second electrode, e.g., top electrode and/or common node, separated by a dielectric material. In some embodiments, the horizontally oriented storage nodes 474 are multi-sided storage nodes, e.g., double sided-capacitors, as shown in FIG. 4. Vertically oriented digit lines 470 are electrically connected to the first source/drain regions 421 of the horizontally oriented access devices 430. In some embodiments, a portion 470 of the vertically oriented digit lines are epitaxially formed (e.g., grown), vertically oriented digit lines 470.

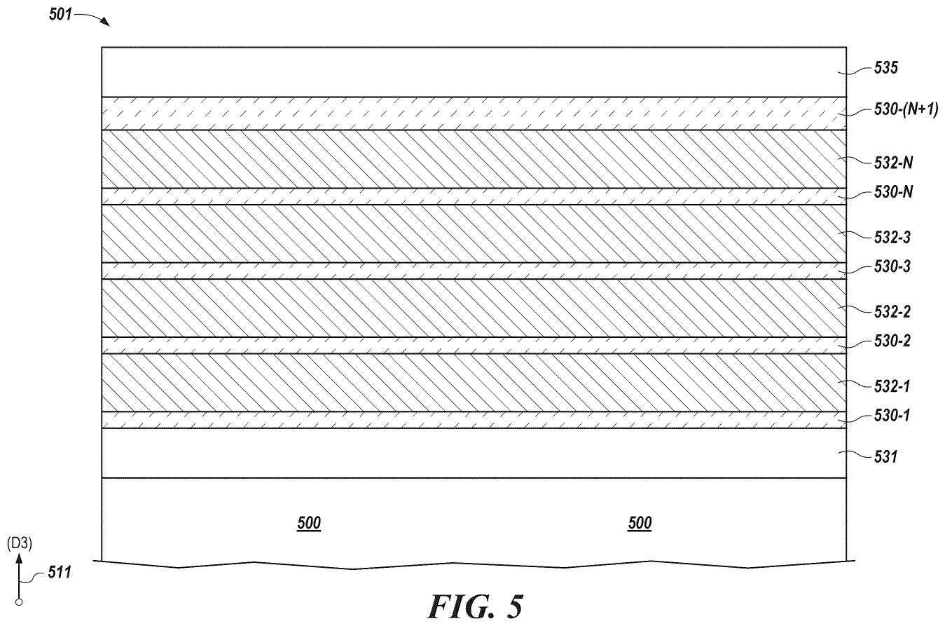

FIG. 5 is a cross-sectional view of a vertical stack in vertical three dimensional (3D) memory in accordance with a number of embodiments of the present disclosure. In the example embodiment shown in the example of FIG. 5, a method of forming the vertical stack 501 can comprise forming alternating layers of a silicon germanium (SiGe) material, 530-1, 530-2, . . . , 530-N (collectively referred to as silicon germanium (SiGe) 530), and a silicon (Si) material, 532-1, 532-2, . . . , 532-N (collectively referred to as single crystalline silicon (Si) material 532), in repeating iterations to form a vertical stack 501 on a working surface of a semiconductor substrate 500. In some embodiments, the silicon germanium (SiGe) material 530 and the silicon (Si) material 532 can be epitaxially grown.

In one embodiment, the silicon germanium (SiGe) 530 can be deposited to have a thickness, e.g., vertical height in the third direction (D3), in a range of five (5) nanometers to thirty (30) nm. In one embodiment, the silicon (Si) material 532 can be deposited to have a thickness (t2), e.g., vertical height, in a range of thirty (30) nanometers (nm) to sixty (60) nm. Embodiments, however, are not limited to these examples. As shown in FIG. 5, a vertical direction 511 is illustrated as a third direction (D3), e.g., z-direction in an x-y-z coordinate system, analogous to the third direction (D3), among first, second, and third directions, shown in FIGS. 1-3.

In some embodiments, the silicon germanium (SiGe), 530-1, 530-2, . . . , 530-N, may be a mix of silicon and germanium. By way of example, and not by way of limitation, the silicon germanium (SiGe) material 530 may be grown on the substrate material 500. Embodiments are not limited to these examples. In some embodiments, the single crystalline silicon (Si) material, 532-1, 532-2, . . . , 532-N, may comprise a silicon (Si) material in a polycrystalline and/or amorphous state. The single crystalline silicon (Si) material, 532-1, 532-2, . . . , 532-N, may be a low doped, p-type (p-) single crystalline silicon (Si) material. The silicon (Si) material, 532-1, 532-2, . . . , 532-N, may also be formed on the silicon germanium (SiGe) 530. If the silicon germanium (SiGe) 530 was epitaxially grown, the seed is turned to pure silicon after the silicon germanium (SiGe) 530 has been formed.

The repeating iterations of alternating silicon germanium (SiGe), 530-1, 530-2, . . . , 530-N layers and single crystalline silicon (Si) material, 532-1, 532-2, . . . , 532-N layers may be deposited according to a semiconductor fabrication process such as chemical vapor deposition (CVD) in a semiconductor fabrication apparatus. Embodiments, however, are not limited to this example and other suitable semiconductor fabrication techniques may be used to deposit the alternating layers of silicon germanium (SiGe) and single crystalline silicon (Si) material, in repeating iterations to form the vertical stack 501.

The layers may occur in repeating iterations vertically. For example, the vertical stack 501 may include: a first silicon germanium (SiGe) material 530-1, a first single crystalline silicon (Si) material 532-1, a second silicon germanium (SiGe) material 530-2, a second single crystalline silicon (Si) material 532-2, a third silicon germanium (SiGe) material 530-3, and a third single crystalline silicon (Si) material 532-3, in further repeating iterations. Embodiments, however, are not limited to this example and more or fewer repeating iterations may be included. In some examples, photolithographic mask 535 may be deposited over a silicon germanium (SiGe) material 530.

In some embodiments, a bottom portion of the vertical stack 501 can be removed to form a second horizontal opening. The bottom portion of the vertical stack 501 can include a layer of silicon germanium (SiGe) material 530 that is closer to the substrate 500 than other layers of silicon germanium (SiGe) material 530, a layer of silicon (Si) material 532 that is closer to the substrate 500 than other layers of silicon (Si) material 532, or both. Further, a dielectric material 531 can be deposited to fill the horizontal opening.

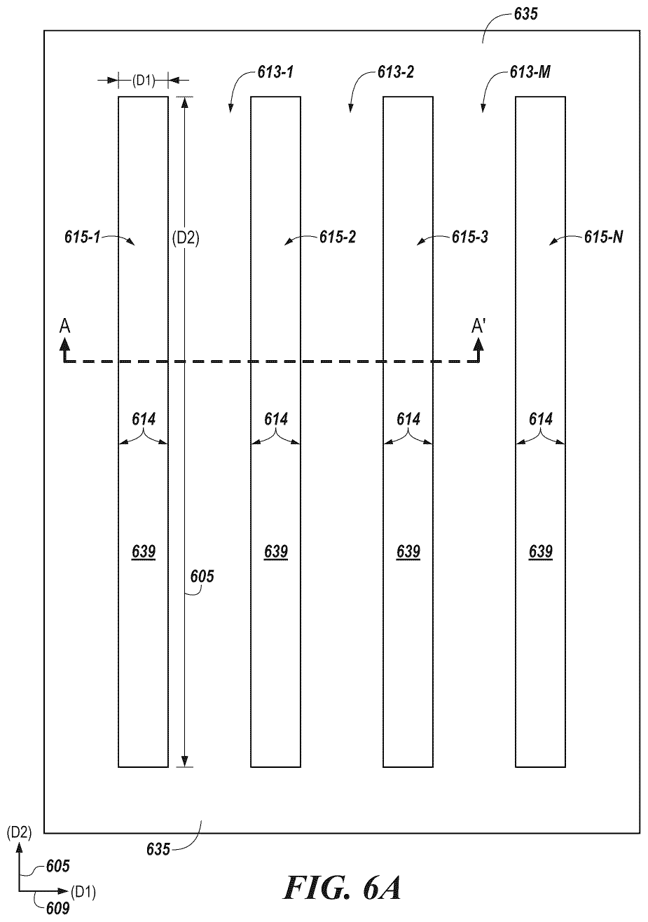

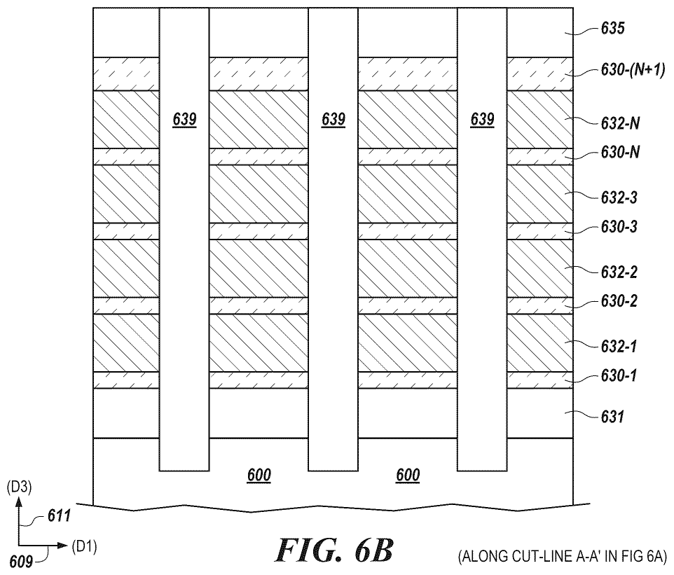

FIG. 6A illustrates an example method, at one stage of a semiconductor fabrication process, for substrate isolation in vertical three dimensional (3D) memory, in accordance with a number of embodiments of the present disclosure. FIG. 6A illustrates a top down view of a semiconductor structure, at a particular point in time, in a semiconductor fabrication process, according to one or more embodiments. In the example embodiment shown in the example of FIG. 6A, the method comprises using an etching process to form a plurality of vertical openings 615-1, 615-2, 615-3, . . . , 615-N (individually or collectively referred to as vertical openings 615), having a first horizontal direction (D1) 609 and a second horizontal direction (D2) 605, through the vertical stack to the substrate. In one example, as shown in FIG. 6A, the plurality of vertical openings (e.g., four vertical openings) 615 are extending predominantly in the second horizontal direction (D2) 605 and may form elongated vertical, pillar columns 613-1, 613-2, . . . , 613-M (collectively and/or independently referred to as vertical, pillar columns 613), with sidewalls 614 in the vertical stack. The plurality of first vertical openings 615 may be formed using photolithographic techniques to pattern a photolithographic mask 635, e.g., to form a hard mask (HM), on the vertical stack prior to etching the plurality of first vertical openings 615. Similar semiconductor process techniques may be used at other points of the semiconductor fabrication process described herein.

The first vertical openings 615 may be filled with a first dielectric material 639. In one example, a spin on dielectric process may be used to fill the first vertical openings 615. In one embodiment, the first dielectric material 639 may be an oxide material. However, embodiments are not so limited.

FIG. 6B is a cross sectional view, taken along cut-line A-A′ in FIG. 6A, showing another view of the semiconductor structure at a particular time in the semiconductor fabrication process for substrate isolation in vertical three dimensional (3D) memory, in accordance with a number of embodiments of the present disclosure. The cross sectional view shown in FIG. 6B shows the repeating iterations of alternating layers of a silicon germanium (SiGe) material 630 and a single crystalline silicon (Si) material 632 on a doped silicon (Si) material 631 and the doped Si material 631 on a semiconductor substrate 600 to form the vertical stack, e.g., vertical stack 501 in FIG. 5.

As shown in FIG. 6B, a plurality of vertical openings may be formed through the layers within the vertically stacked memory cells, stacked in a third direction (D3) 611 to expose vertical sidewalls in the vertical stack and form elongated vertical pillar columns 613 and then filled with a first dielectric material 639. The first vertical openings 615 may be formed through the repeating iterations of the silicon germanium (SiGe) material 630 and the single crystalline silicon (Si) material 632. As such, the first vertical openings 615 may be formed through a first silicon germanium (SiGe) material 630-1, a first single crystalline silicon (Si) material 632-1, a second silicon germanium (SiGe) material 630-2, a second single crystalline silicon (Si) material 632-2, a third silicon germanium (SiGe) material 630-3, and a third single crystalline silicon (Si) material 632-3. Embodiments, however, are not limited to the vertical opening(s) shown in FIG. 6B. Multiple vertical openings may be formed through the layers of materials. The vertical openings may be formed to expose vertical sidewalls in the vertical stack. The vertical openings may extend in a first direction (D1) 609 to form elongated vertical, pillar columns with vertical sidewalls in the vertical stack and then filled with first dielectric 639.

As shown in FIG. 6B, a first dielectric material 639, such as an oxide or other suitable spin on dielectric (SOD), may be deposited in the first vertical openings 615, using a process such as CVD, to fill the first vertical openings 615. First dielectric material 639 may also be formed from a silicon nitride (Si₃N₄) material. In another example, the first dielectric material 639 may include silicon oxy-nitride (SiOₓN_{y}), and/or combinations thereof. Embodiments are not limited to these examples. The plurality of first vertical openings 615 may be formed using photolithographic techniques to pattern a photolithographic mask 635, e.g., to form a hard mask (HM), on the vertical stack prior to etching the plurality of first vertical openings 615. In one embodiment, hard mask 635 may be deposited over a silicon germanium (SiGe) material 630. Similar semiconductor process techniques may be used at other points of the semiconductor fabrication process described herein.

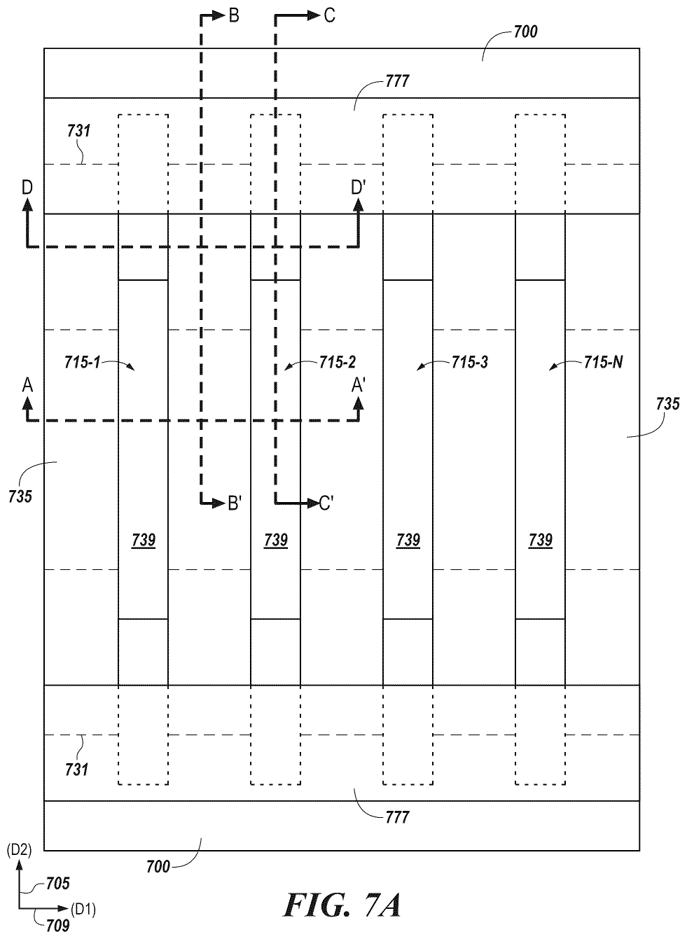

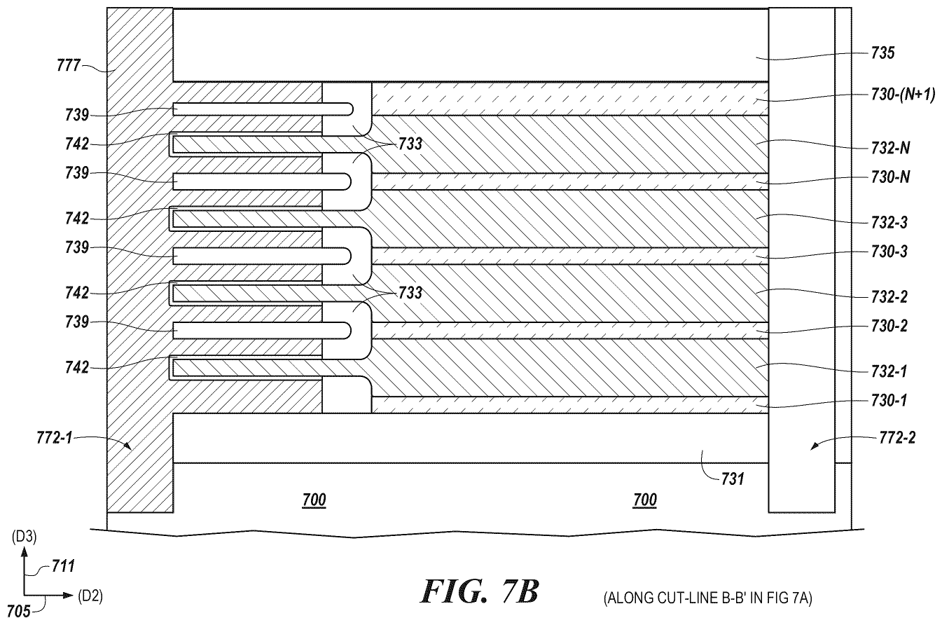

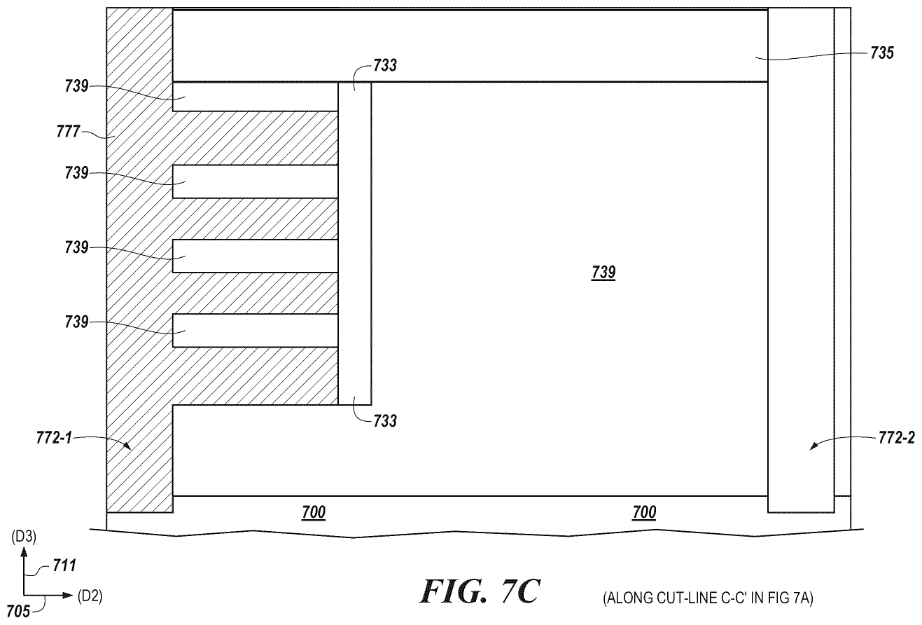

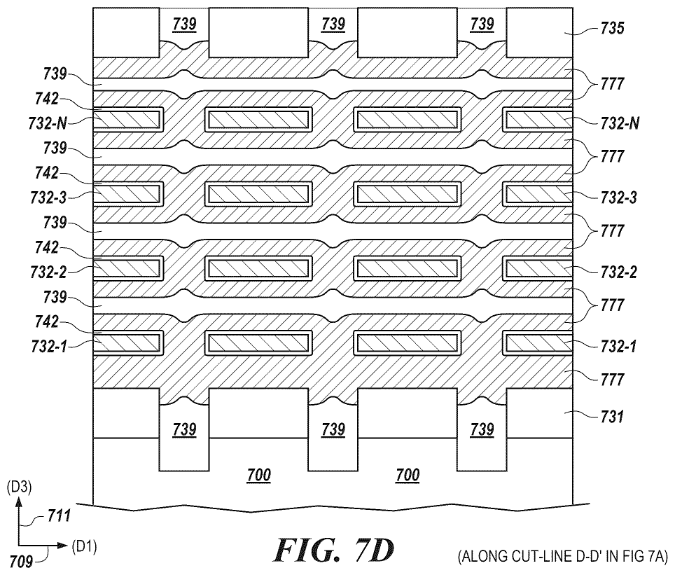

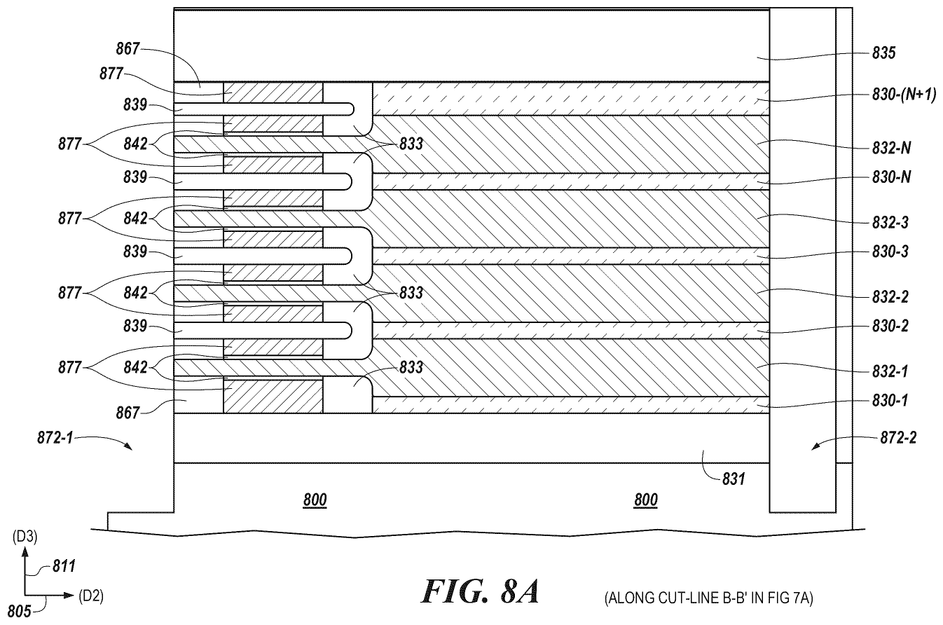

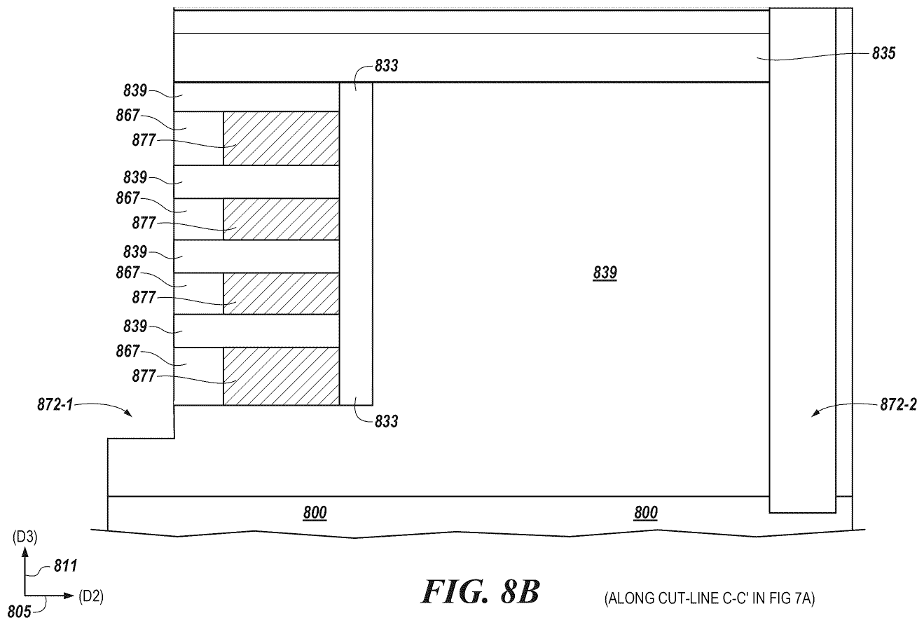

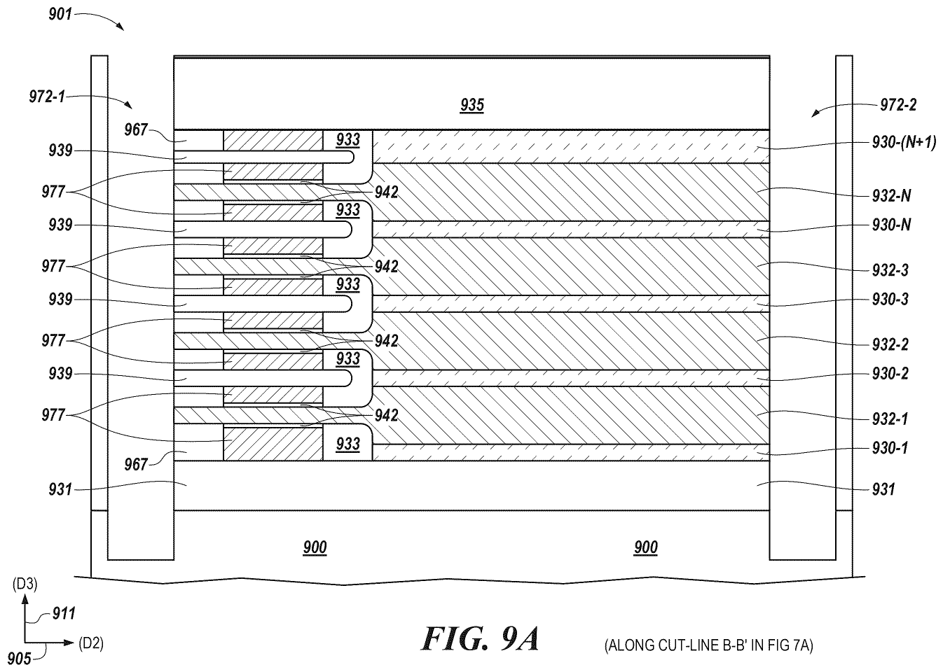

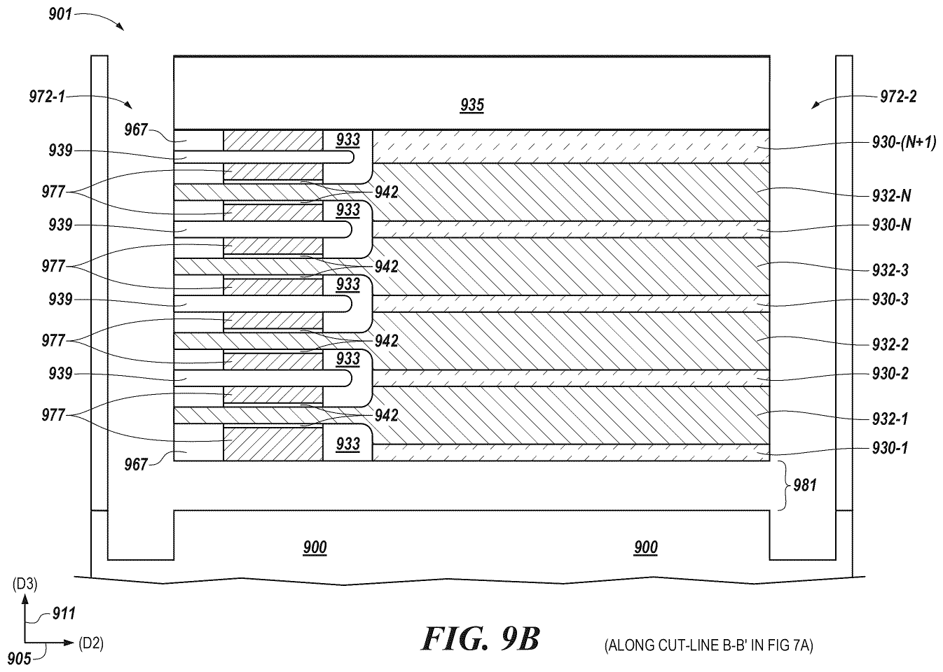

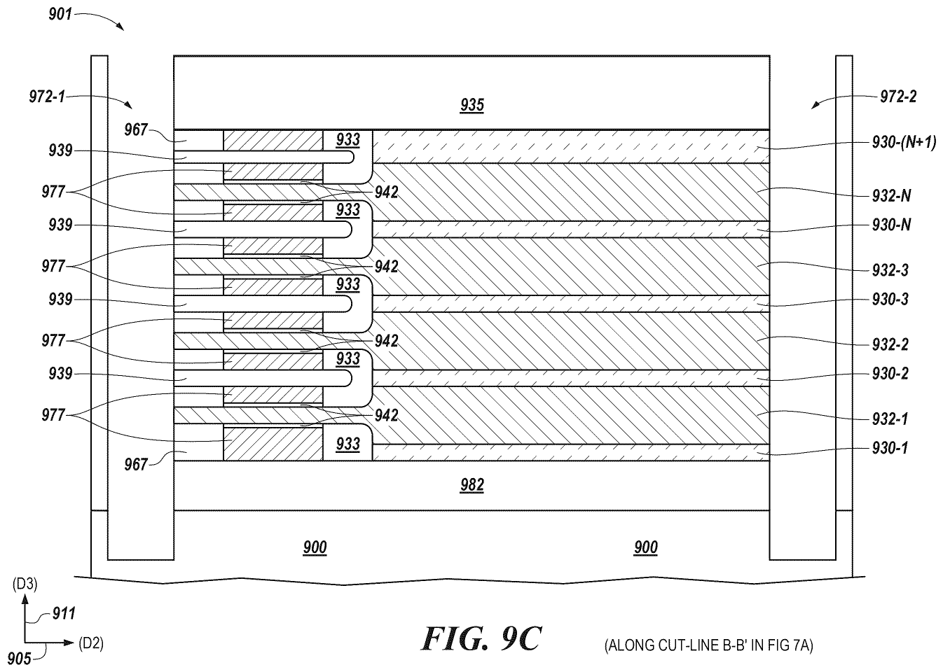

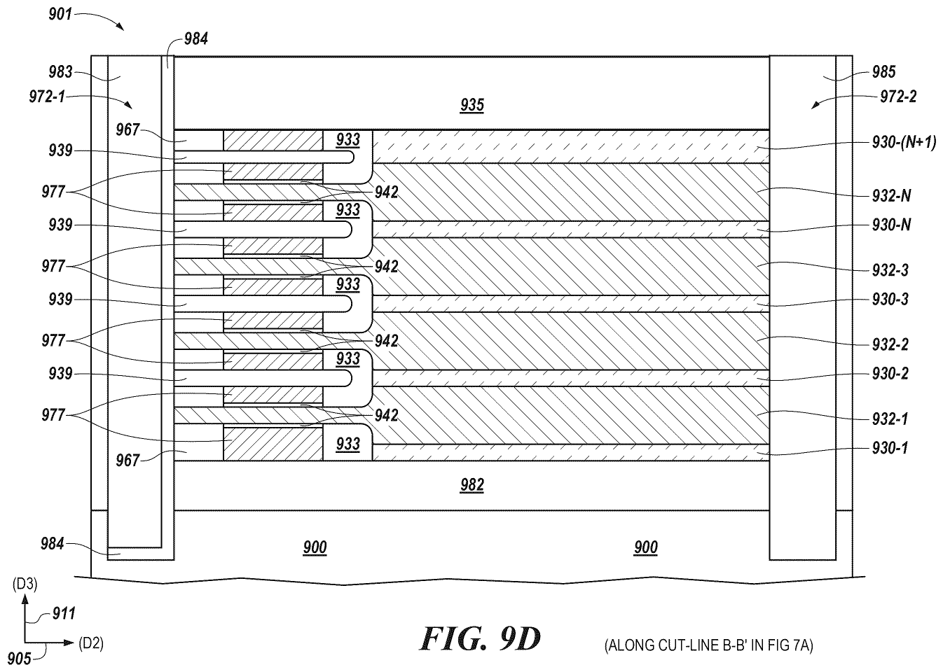

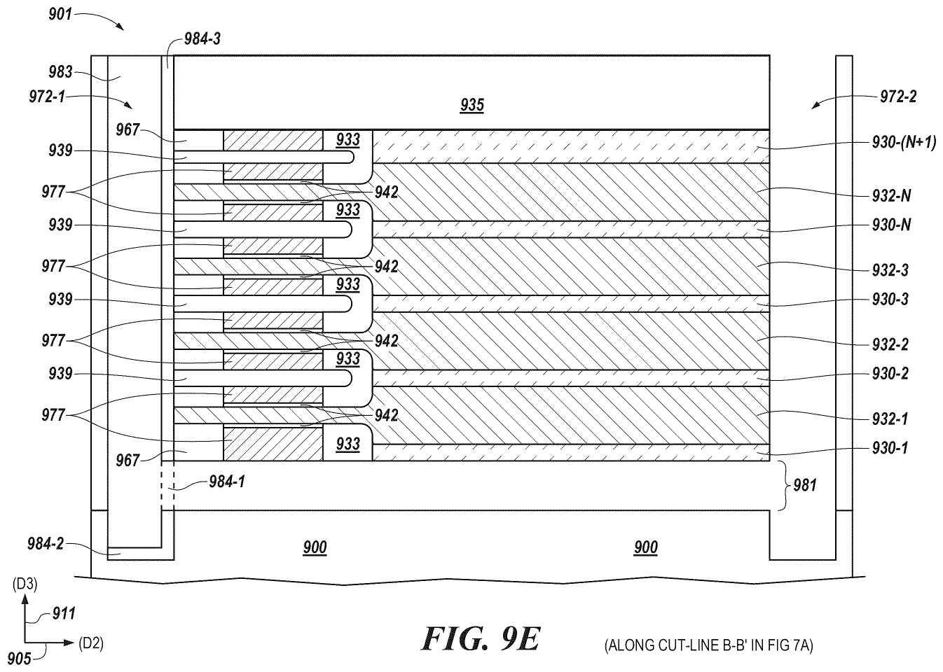

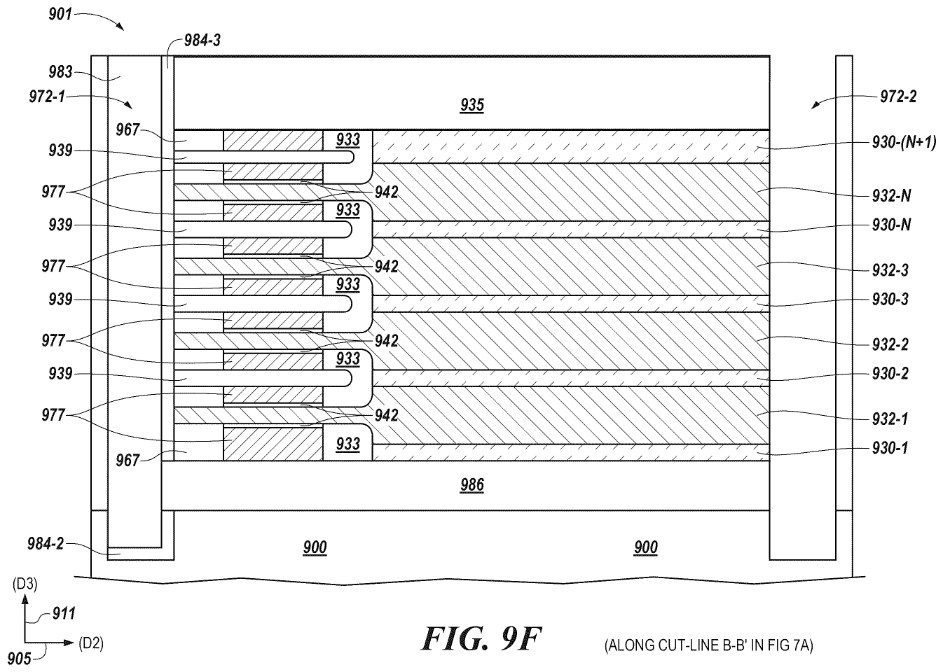

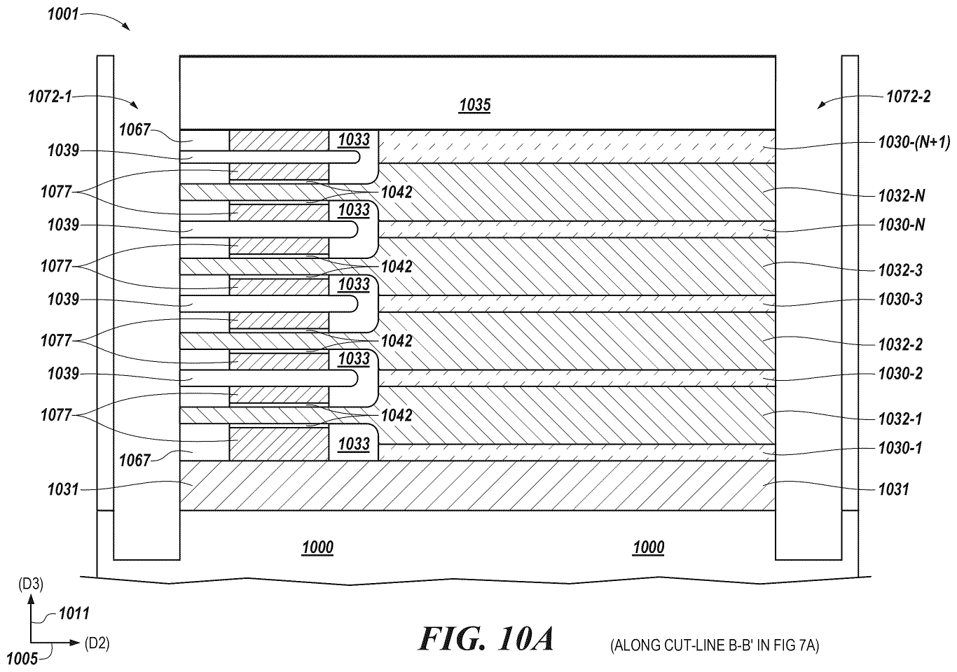

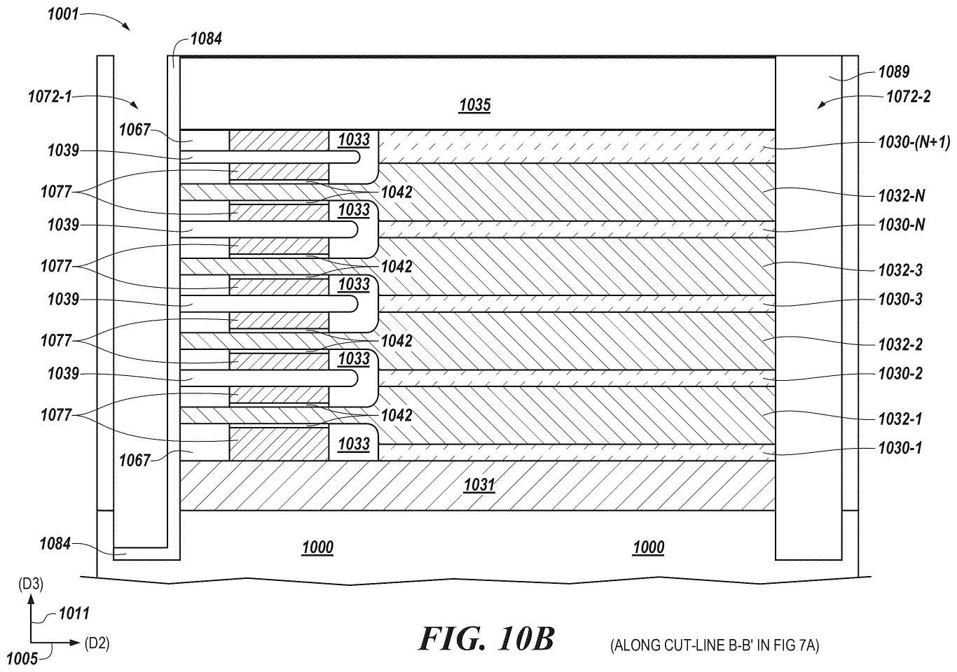

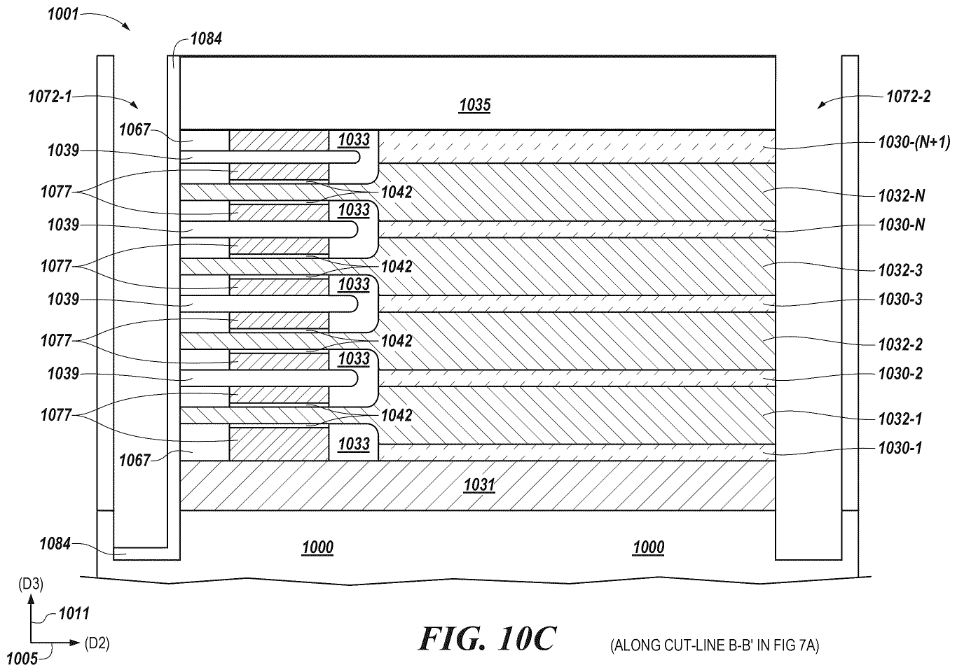

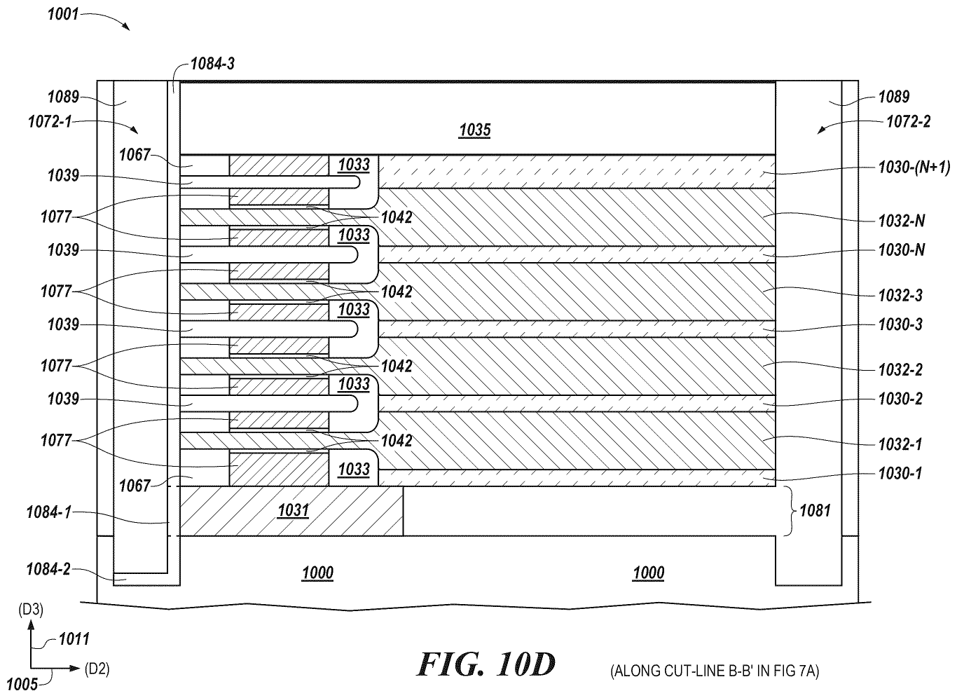

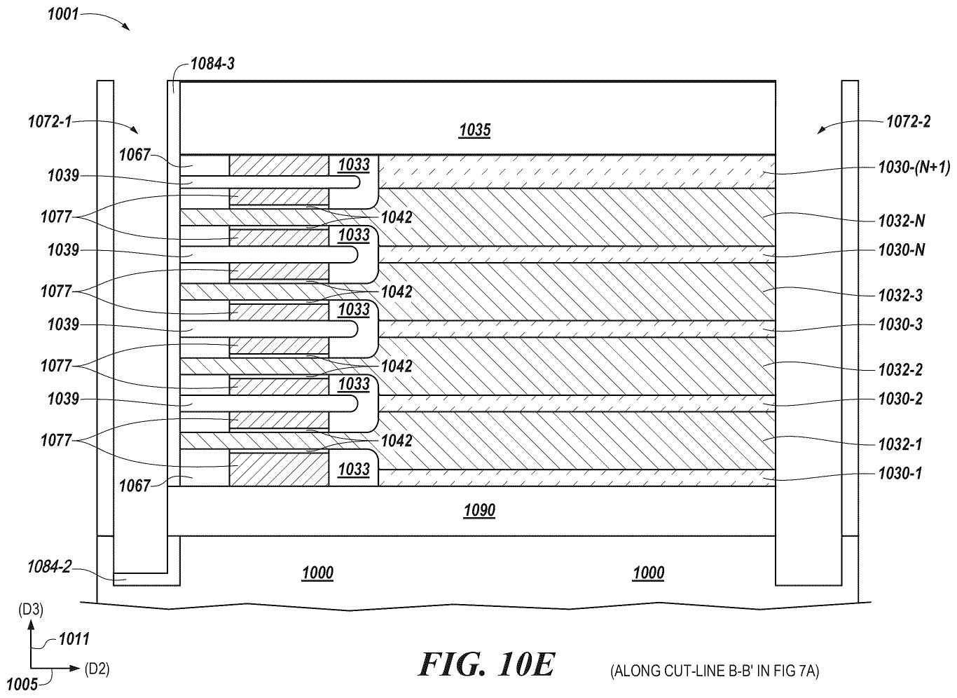

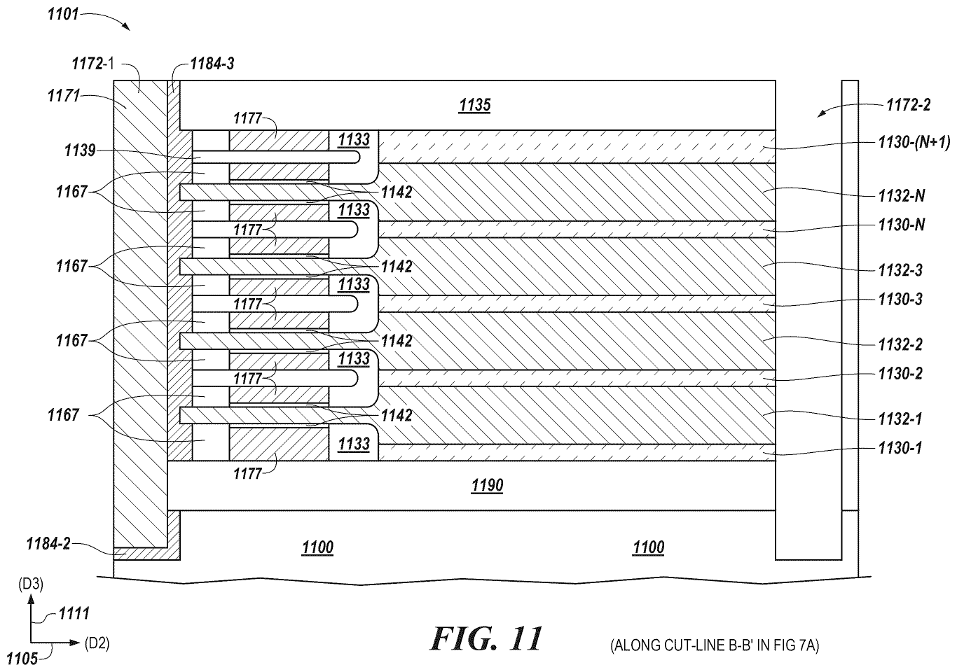

FIG. 7A illustrates an example method, at another stage of a semiconductor fabrication process for substrate isolation in vertical three dimensional (3D) memory, in accordance with a number of embodiments of the present disclosure. FIG. 7A illustrates a top down view of a semiconductor structure, at a particular point in time, in a semiconductor fabrication process, according to one or more embodiments. In the example embodiment of FIG. 7A, the method comprises using a photolithographic process to pattern the photolithographic mask 735. A first conductive material 777 may be deposited above the vertical openings 715. The first conductive material 777 may be deposited in the continuous first horizontal openings to form horizontally oriented access lines opposing channel regions of the single crystalline silicon (Si) material 732.

FIG. 7B illustrates a cross sectional view, taken along cut-line B-B′ in FIG. 7A, showing another view of the semiconductor structure at this particular point in one example semiconductor fabrication process for substrate isolation in vertical three dimensional (3D) memory in accordance with embodiments of the present disclosure. The cross sectional view shown in FIG. 7B is illustrated extending in the second horizontal direction (D2) 705, left and right along the plane of the drawing sheet.

A process of depositing and etching materials is used to form the structure shown in FIG. 7B. In some embodiments, the process of depositing and etching materials can include forming horizontally oriented access devices and horizontally oriented storage nodes to form an array of vertically stacked memory cells. Each of the horizontally oriented access devices can have first source/drain regions and second source/drain regions separated by channel regions. In some embodiments, gates can be formed fully around every surface of the channel regions as gate all around (GAA) structures on a gate dielectric material. Further, in some embodiments, the second source/drain regions can be coupled to storage nodes.

The semiconductor structure shown in FIG. 7B shows the semiconductor structure after the silicon germanium (SiGe) layers are selectively etched to form a plurality of first horizontal openings a first length from first vertical openings 772-1. In some embodiments, the second vertical openings 772-2 can be formed to a depth in a range of 0.5 to one (1) micrometer (μm). Further, in some embodiments, each of the first vertical openings 772-1 can be formed to have an aspect ratio in a range of 15-20. In some embodiments, the selective etch that forms to plurality of second horizontal openings can also reduce a vertical thickness of the silicon (Si) layers. In some embodiments, a vertical thickness of a portion of each of the silicon (Si) layers can be reduced to a vertical thickness in a range of 100-150 Angstroms (Å).

The process of forming the horizontally oriented access devices can further include conformally depositing a second dielectric material 733 on exposed surfaces in the plurality of first horizontal openings and depositing the first dielectric material 739 to fill the plurality of first horizontal openings. The second dielectric material 733 can be selectively etched from the plurality of first horizontal openings a second length (L2) from the first vertical opening 772-1. In some embodiments, the second length (L2) can be a length in a range of 130-170 nanometers (nm).

A first conductive material 777 may be deposited in the first horizontal opening on the gate dielectric material 742 after selectively etching the second dielectric material 739. The first conductive material 777 may be deposited around the single crystalline silicon (Si) material 732 such that the first conductive material 777 may have a top portion above the single crystalline silicon (Si) material 732 and a bottom portion below the single crystalline silicon (Si) material to form a gate all around (GAA) gate structure, at a channel of an access device region. The first conductive material 777 may be conformally deposited into vertical openings 772-1 and fill the continuous horizontal openings up to the unetched portions, the first dielectric material 739, and the second dielectric material 733. The conductive material 777 may be conformally deposited using a chemical vapor deposition (CVD) process, plasma enhanced CVD (PECVD), atomic layer deposition (ALD), or other suitable deposition process.

In some embodiments, the first conductive material, 777, may comprise one or more of a doped semiconductor, e.g., doped silicon, doped germanium, etc., a conductive metal nitride, e.g., titanium nitride, tantalum nitride, etc., a metal, e.g., tungsten (W), titanium (Ti), tantalum (Ta), ruthenium (Ru), cobalt (Co), molybdenum (Mo), etc., and/or a metal-semiconductor compound, e.g., tungsten silicide, cobalt silicide, titanium silicide, etc., and/or some other combination thereof. The first conductive material 777 entwined with the gate dielectric material 742 may form horizontally oriented access lines opposing a channel region of the single crystalline silicon (Si) material (which also may be referred to as word lines).

FIG. 7C illustrates a cross sectional view, taken along cut-line C-C′ in FIG. 7A, showing another view of the semiconductor structure at this particular point in one example semiconductor fabrication process of an embodiment of the present disclosure. The cross sectional view shown in FIG. 7C is illustrated extending in the second horizontal direction (D2) 705, left and right in the plane of the drawing sheet, along an axis of the repeating iterations of alternating layers of continuous horizontal openings and single crystalline silicon (Si) material 732.

In FIG. 7C, first dielectric material 739 is shown spaced along a second horizontal direction (D2) 705, extending into and out from the plane of the drawings sheet, for a three dimensional (3D) array of vertically oriented memory cells, which can include vertical openings 772-1, 772-2. At the left end of the drawing sheet is shown the repeating iterations of alternating layers of single crystalline silicon (Si) material 732, separated by continuous horizontal openings in a first direction (D1) 709 filled with a first conductive material 777. The first conductive material 777 may be conformally deposited into vertical openings 772-1 and into the horizontal openings. The first conductive material 777 is formed on the gate dielectric material (e.g., gate dielectric material 742 in FIG. 7B). At the right hand of the drawing sheet, the first dielectric material 739 may be seen, separating access device and storage node regions in the first direction (D1) 709, and having the horizontal opening filled with the second dielectric material 733 and the first dielectric material 739.

FIG. 7D illustrates a cross sectional view, taken along cut-line D-D′ in FIG. 7A, showing another view of the semiconductor structure at this particular point in one example semiconductor fabrication process for substrate isolation in vertical three dimensional (3D) memory, in accordance with a number of embodiments of the present disclosure. The cross sectional view shown in FIG. 7D is illustrated, right to left in the plane of the drawing sheet, extending in the first direction (D1) 709 along an axis of the repeating iterations of alternating layers of first dielectric material 739 and single crystalline silicon (Si) material 732 wrapped with a gate dielectric material 742. The gate dielectric material 742 may be conformally deposited fully around every surface of the single crystalline silicon (Si) material 732, to form gate all around (GAA) gate structures, at the channels of the access device regions. The first conductive material 777 may fill the spaces adjacent the bridged single crystalline silicon (Si) material 732. The single crystalline silicon (Si) material 732 may be surrounded by the first conductive material 777 formed on the gate dielectric material 742. The first conductive material 777 may be conformally deposited fully around every surface of the single crystalline silicon (Si) material 732, to form gate all around (GAA) gate structures, at the channels of the access device regions. In FIG. 7D, the first conductive material, 777 is shown filling in the space in the second horizontal openings left by the etched second dielectric material 733.

FIG. 8A illustrates an example method, at another stage of a semiconductor fabrication process, for substrate isolation in vertical three dimensional (3D) memory, in accordance with a number of embodiments of the present disclosure. The cross sectional view shown in FIG. 8A is illustrated extending in the second horizontal direction (D2) 805, left and right along the plane of the drawing sheet, along an axis of the repeating iterations of alternating layers of the silicon germanium (SiGe) material 830 and the single crystalline silicon (Si) material 832.

A first conductive material 877 was deposited on the gate dielectric material 842 and formed around the single crystalline silicon (Si) material 832, recessed back, to form gate all around (GAA) structure opposing channel regions of the single crystalline silicon (Si) material 832. The first conductive material 877, formed on the gate dielectric material 842, may be recessed and etched away from the vertical opening 872-1. In some embodiments, the first conductive material 877 may be etched using an atomic layer etching (ALE) process. In some embodiments, the first conductive material 877 may be etched using an isotropic etch process. The first conductive material 877 may be selectively etched leaving the oxide material 842 covering the epitaxially grown, single crystalline silicon (Si) material and the first dielectric material 842 intact. The first conductive material 877 may be selectively etched in the second direction, in the continuous horizontal openings, a third distance (DIST 3) in a range of twenty (20) to fifty (50) nanometers (nm) back from the first vertical opening 872-1. The first conductive material 877 may be selectively etched around the single crystalline silicon (Si) material 832 back into the continuous horizontal openings extending in the first horizontal direction.

An interlayer dielectric (ILD) fill material 867 can be deposited on the gate dielectric material 842 and formed around the single crystalline silicon (Si) material 832. Horizontal access devices of a vertical 3D memory array can include the first dielectric material 839, the second dielectric material 833, the first conductive material 877, and the ILD fill material 867.

FIG. 8B illustrates an example method, at another stage of a semiconductor fabrication process, for substrate isolation in vertical three dimensional (3D) memory, in accordance with a number of embodiments of the present disclosure. The cross sectional view shown in FIG. 8B is illustrated extending in the second direction (D2) 805, left and right in the plane of the drawing sheet, along an axis of the repeating iterations of alternating layers of the etched first conductive material 877 and single crystalline silicon (Si) material 832.

In FIG. 8B, first dielectric material 839 is shown spaced along a first horizontal direction (D1) 809 extending into and out from the plane of the drawings sheet, for a three dimensional (3D) array of vertically oriented memory cells. At the left end of the drawing sheet is shown the first conductive material 877 formed on the gate dielectric material 842, was etched away from the vertical opening 872-1. The first conductive material 877, formed on the gate dielectric material 842, is also recessed back in the continuous horizontal openings extending in the first horizontal direction 809. The first conductive material 877 may be selectively etched leaving the oxide material 842 covering the single crystalline silicon (Si) material 832 intact. In some embodiments, the first conductive material 877 may be etched using an atomic layer etching (ALE) process. In some embodiments, the first conductive material 877 may be etched using an isotropic etch process.

FIGS. 9A to 9F illustrate an example method, at one stage of a semiconductor fabrication process, for isolating substrate 900 in three dimensional (3D) arrays of vertically stacked memory cells, having horizontally oriented access devices and storage nodes, in accordance with a number of embodiments of the present disclosure. After forming a doped silicon (Si) material 931 on the substrate 900 and a number of layers of a vertical stack 901 including alternating layers of silicon germanium (SiGe) material 930 and Si material 932 followed by a photolithographic mask 935, the substrate 900 can be isolated.

As illustrated in FIG. 9A, a method for isolating the substrate 900 can include forming a first vertical opening 972-1 in a vertical direction 911 through the vertical stack 901 and into the substrate material 900 and extending predominantly in a first horizontal direction 905 to expose first vertical sidewalls in the vertical stack 901 and the substrate material 900. The method can further include forming a second vertical opening 972-2 through the vertical stack 901 and into the substrate material 900 and extending predominantly in a second horizontal direction 905 to expose second vertical sidewalls in the vertical stack 901 and the substrate material 900. In some examples, the first vertical opening 972-1 and the second vertical opening 972-2 can be formed at the same time.

A first conductive material 977 can be deposited on a gate dielectric material 942 and formed around the Si material 932, recessed back, to form GAA structure opposing channel regions of the Si material 932. The first conductive material 977, formed on the gate dielectric material 942, may be recessed and etched away from the first vertical opening 972-1. The first conductive material 977 may be selectively etched leaving the oxide material 942 covering the epitaxially grown, Si material 932 and the first dielectric material 942 intact. The first conductive material 977 may be selectively etched in the second direction, in the continuous horizontal openings. The first conductive material 977 may be selectively etched around the Si material 932 back into the continuous horizontal openings extending in the first horizontal direction.

An interlayer dielectric (ILD) fill material 967 can be deposited on the gate dielectric material 942 and formed around the Si material 932. Horizontal access devices of a vertical 3D memory array can include the first dielectric material 939, the second dielectric material 933, the first conductive material 977, and the ILD fill material 967.

As illustrated in FIG. 9B, the method for isolating the substrate 900 can further include selectively removing the doped Si material 931 to form a horizontal opening 981 from the first vertical opening 972-1 to the second vertical opening 972-2. In a number of embodiments, the doped Si material 931 can be selectively removed using a wet etching process.

The method for isolating the substrate 900 can further include depositing a first material 982 in the horizontal opening 981 via the first vertical opening 972-1 and/or the second vertical opening 972-2. The first material 982 can then be selectively removed from the first vertical opening 972-1 and the second vertical opening 972-2, as illustrated in FIG. 9C. In some examples, the first material 982 can be a metal or a metal oxide.

As illustrated in FIG. 9D, the method for isolating the substrate 900 can further include depositing a removable sacrificial material 985 in the second vertical opening 972-2, depositing a digit line liner 984 in a vertical portion of the first vertical opening 972-1, and depositing an insulation material 983 in the first vertical opening 972-1 to fill a remaining portion of the first vertical opening 972-1.

The method for isolating the substrate 900 can further include selectively removing the sacrificial material 985 in the second vertical opening 972-2 and selectively removing the first material 982 in the horizontal opening 981 and a first portion 984-1 of the digit line liner 984 via the second vertical opening 972-2, as illustrated in FIG. 9E. The first portion 984-1 of the digit line liner 984, prior to removal, can be formed on a sidewall of the first material 982 and the third portion 984-3 of the digit line liner 984 can be formed on the vertical stack 901 including a sidewall of the layers of the Si material 932. The digit line liner 984 can be deposited on the vertical portion of the first vertical opening 972-1, as well as, the substrate 900. As such, the second portion 984-2 of the digit line liner 984 can be formed on the substrate 900.

As illustrated in FIG. 9F, the method for isolating the substrate 900 can further include depositing a second material 986 on the second portion 984-2 of the digit line liner 984 and in the horizontal opening 981 via the second vertical opening 972-2. The second material 986 can be an oxide or a material with a dielectric constant greater than a dielectric constant of silicon dioxide. The second material 986 can separate the second portion 984-2 of the digit line liner 984 from the third portion 984-3 of the digit line liner 984. The vertical stack 901 can be isolated from the substrate 900 by separating the second portion 984-2 of the digit line liner 984 from the third portion 984-3 of the digit line liner 984.

Isolating the vertical stack 901 and the third portion 984-3 of the digit line liner 984 from the substrate 900 can avoid shorting. Using a doped Si material 931 removal process for isolating the vertical stack 901 and the third portion 984-3 of the digit line liner 984 from the substrate 900, as disclosed in FIGS. 9A to 9F, can prevent the need for trench depth alignment with the first layer of the vertical stack 901 and enables the first vertical opening 972-1 and the second vertical opening 972-2 to be etched at the same time.

FIG. 10A to 10E illustrate an example method, at one stage of a semiconductor fabrication process, for isolating substrate 1000 in three dimensional (3D) arrays of vertically stacked memory cells, having horizontally oriented access devices and storage nodes, in accordance with a number of embodiments of the present disclosure. After forming a doped silicon (Si) material 1031 (e.g., N+ doped Si material) on the substrate 1000 and a number of layers of a vertical stack 1001 including alternating layers of silicon germanium (SiGe) material 1030 and Si material 1032 followed by a photolithographic mask 1035, the substrate 1000 can be isolated.

As illustrated in FIG. 10A, a method for isolating the substrate 1000 can include forming a first vertical opening 1072-1 in a vertical direction 1011 through the vertical stack 1001 and into the substrate material 1000 and extending predominantly in a first horizontal direction 1005 to expose first vertical sidewalls in the vertical stack 1001 and the substrate material 1000. The method can further include forming a second vertical opening 1072-2 through the vertical stack 1001 and into the substrate material 1000 and extending predominantly in a second horizontal direction 1005 to expose second vertical sidewalls in the vertical stack 1001 and the substrate material 1000. In some examples, the first vertical opening 1072-1 and the second vertical opening 1072-2 can be formed at the same time.

A first conductive material 1077 can be deposited on a gate dielectric material 1042 and formed around the Si material 1032, recessed back, to form GAA structure opposing channel regions of the Si material 1032. The first conductive material 1077, formed on the gate dielectric material 1042, may be recessed and etched away from the first vertical opening 1072-1. The first conductive material 1077 may be selectively etched leaving the oxide material 1042 covering the epitaxially grown, Si material 1032 and the first dielectric material 1042 intact. The first conductive material 1077 may be selectively etched in the second direction, in the continuous horizontal openings. The first conductive material 1077 may be selectively etched around the Si material 1032 back into the continuous horizontal openings extending in the first horizontal direction.

An interlayer dielectric (ILD) fill material 1067 can be deposited on the gate dielectric material 1042 and formed around the Si material 1032. Horizontal access devices of a vertical 3D memory array can include the first dielectric material 1039, the second dielectric material 1033, the first conductive material 1077, and the ILD fill material 1067.

The method for isolating the substrate 1000 can further include depositing a removable sacrificial material 1089 in the second vertical opening 1072-2 and depositing a digit line liner 1084 in a vertical portion of the first vertical opening 1072-1, as illustrated in FIG. 10B. As illustrated in FIG. 10C, the method for isolating the substrate 1000 can further include selectively removing the sacrificial material 1089 from the second vertical opening 1072-2.

The method for isolating the substrate 1000 can further include selectively removing the N+ doped Si material 1031 and a first portion 1084-1 of the digit line liner 1084 using a galvanic corrosion process to form a horizontal opening 1081, as illustrated in FIG. 10D. The N+ doped Si material 1031 can be removed without removing the alternating layers of the SiGe material 1030 and the Si material 1032. The galvanic corrosion process can include exposing the digit line liner 1084 and the N+ doped Si material 1031, which are in ohmic contact, to an electrolyte. The electrolyte can be phosphoric acid (H3PO4), for example. The digit line liner 1084 and the N+ doped Si material 1031 can be exposed to the electrolyte via the first vertical opening 1072-1 and/or the second vertical opening 1072-2.

As illustrated in FIG. 10E, the method for isolating the substrate 1000 can further include depositing a dielectric material 1090 on a second portion 1084-2 of the digit line liner 1084 and in the horizontal opening 1081 via the second vertical opening 1072-2. The third portion 1084-3 of the digit line liner 1084 can be formed on the vertical stack 1001 and the second portion 1084-2 of the digit line liner 1084 can be formed on the substrate 1000. For example, a portion of the dielectric material 1090 can be formed between the third portion 1084-3 of the digit line liner 1084 and the second portion 1084-2 of the digit line liner 1084. The vertical stack 1001 can be formed on the substrate 1000 and the vertical stack 1001 and the third portion 1084-3 of the digit line liner 1084 can be insulated from the second portion 1084-2 of the digit line liner 1084 and the substrate 1000 by the dielectric material 1090. Isolating the vertical stack 1001 and the third portion 1084-3 of the digit line liner 1084 from the second portion 1084-2 of the digit line liner 1084 and the substrate 1000 can avoid shorting.

Using an N+ doped Si material 1031 removal process for isolating the vertical stack 1001 and the third portion 1084-3 of the digit line liner 1084 from the substrate 1000, as disclosed in FIGS. 10A to 10E, can prevent the need for trench depth alignment with the first layer of the vertical stack 1001 and enables the first vertical opening 1072-1 and the second vertical opening 1072-2 to be etched at the same time.

FIG. 11 illustrates an example method, at another stage of a semiconductor fabrication process, for substrate isolation in vertical three dimensional (3D) memory, in accordance with a number of embodiments of the present disclosure. The cross sectional view shown in FIG. 11 is illustrated extending in the second horizontal direction (D2) 1105, left and right along the plane of the drawing sheet.

FIG. 11 illustrates an example embodiment of a vertical digit line formed by the combination of second conductive material (e.g., a first portion of digit line liner) 1184-1 and third conductive material 1171 formed within the first vertical opening 1172-1. In one example, a second conductive material 1184-1 may be conformally formed in the first vertical opening 1172-1. The second conductive material 1184-1 may be formed from a conformal deposition of a highly doped polysilicon material. In one example, the dopant can include a high concentration n-type dopant. In a further example, the polysilicon may first be deposited and then a high concentration of n-type dopant may be implanted therein from the second conductive material 1184-1. One example of forming the second conductive material 1184-1 includes conformally depositing a highly phosphorus (P) doped (n+-type dopant) poly-silicon germanium (SiGe) material into the first vertical openings for the second conductive material 1184-1.

A third conductive material 1171 may be deposited into the first vertical opening 1172-1 on the second conductive material 1184-1 to fill the vertical opening 1172-1 as shown in FIG. 11. In some embodiments, the third conductive material 1171 may comprise one or more of a doped semiconductor material, e.g., doped silicon, doped germanium, etc., a conductive metal nitride, e.g., titanium nitride, tantalum nitride, etc., a metal, e.g., tungsten (W), titanium (Ti), tantalum (Ta), ruthenium (Ru), cobalt (Co), molybdenum (Mo), etc., and/or a metal-semiconductor compound, e.g., tungsten silicide, cobalt silicide, titanium silicide, etc., and/or some other combination thereof. The third conductive material 1171 coupled to the second conductive material 1184-1 may be formed vertically adjacent first source/drain regions to horizontal access devices to form vertical digit lines.

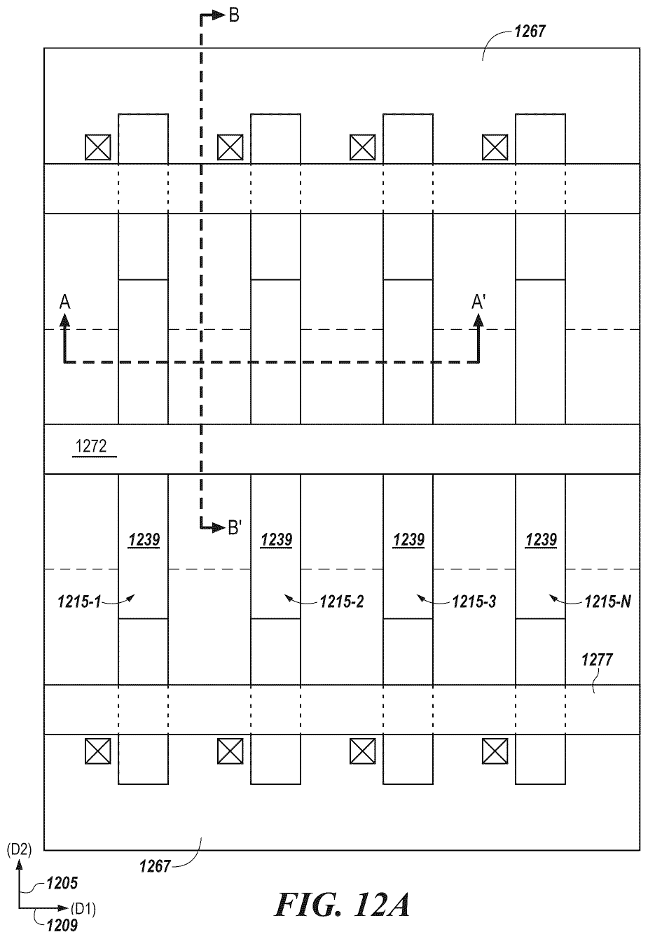

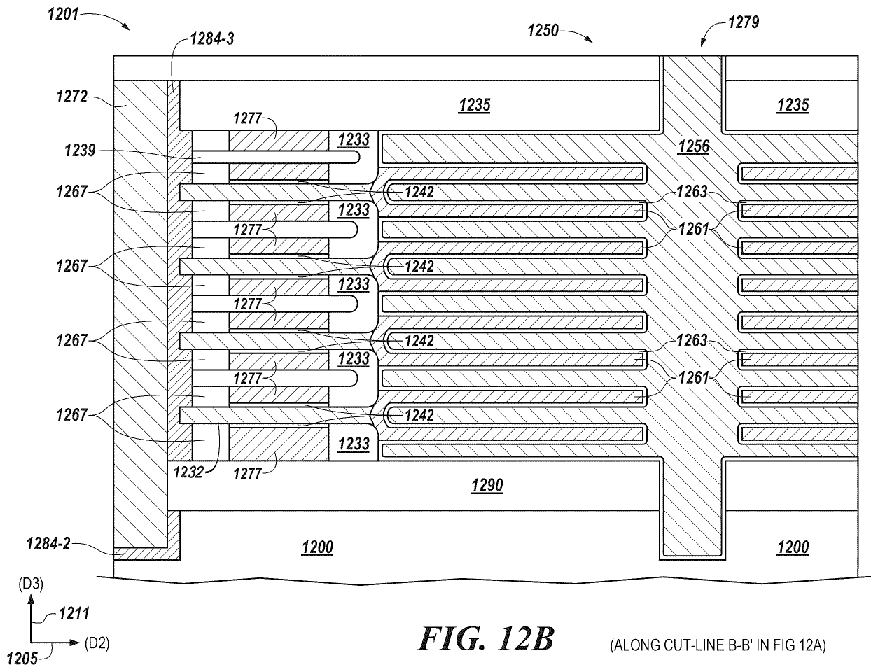

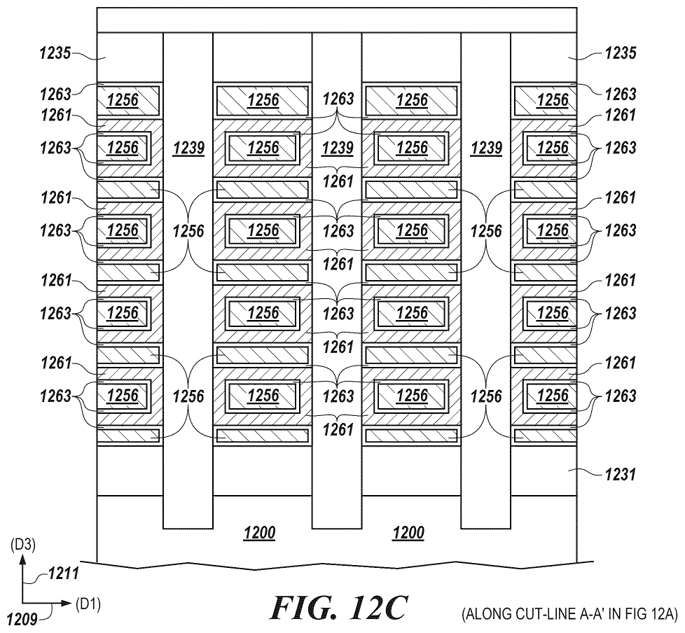

FIG. 12A illustrates an example method, at another stage of a semiconductor fabrication process, for epitaxial digit line growth in vertical three-dimensional (3D) memory, such as illustrated in FIGS. 1-3, and in accordance with a number of embodiments of the present disclosure. A vertical opening can be formed in a storage node region through the vertical stack and extending predominantly in the first horizontal direction (D1) 1209.

FIG. 12B is a cross sectional view, taken along cut-line B-B′ in FIG. 12A, showing another view of the semiconductor structure at a particular time in the semiconductor fabrication process. In FIG. 12B, the one or more etchant processes can be utilized to form the storage node region 1250. The storage node region 1250 can include storage nodes (e.g., horizontally oriented capacitor cells) having the first electrodes 1261, e.g., bottom electrodes to be coupled to source/drain regions of horizontal access devices, and second electrodes 1256, e.g., top electrodes to be coupled to a common electrode plane such as a ground plane. The storage nodes are shown formed in a third horizontal opening 1279, extending in second direction (D2) 1205, left and right in the plane of the drawing sheet, a third distance from the vertical opening formed in the vertical stack and along an axis of orientation of the horizontal access devices and horizontal storage nodes of the arrays of vertically stacked memory cells of the three-dimensional (3D) memory. In FIG. 12B, a neighboring, horizontal access line is illustrated adjacent the second dielectric material 1233, with a portion of the first conductive material 1277 located above the Si material 1232, and a portion of the first conductive material 1277 located below the Si material 1232 extending in a direction inward and outward from the plane and orientation of the drawing sheet.

Additionally, as illustrated in FIG. 12B, the ILD material 1267 can be removed from the vertical opening 1272 and up to a vertical sidewall of the vertical opening 1272, resulting in a vertical stack in the vertical opening 1272 of alternating ILD material 1267, dielectric material 1239, ILD material 1267, gate dielectric material 1242, Si material 1232, dielectric material 1239, ILD fill material 1267, etc.

FIG. 12C is a cross sectional view, taken along cut-line A-A′ in FIG. 12A, showing another view of the semiconductor structure at a particular time in the semiconductor fabrication process. The cross-sectional view shown in FIG. 12C is away from the plurality of separate, horizontal access lines, and shows repeating iterations of alternating layers of second electrodes 1256 separated by horizontally oriented capacitor cells having first electrodes 1261, e.g., bottom cell contact electrodes, cell dielectric material 1263, and top, common node electrodes, on a semiconductor substrate 1200 to form the vertical stack. In the example embodiment of FIG. 12C, the first electrodes 1261, e.g., bottom electrodes to be coupled to source/drain regions of horizontal access devices, and second electrodes 1256 are illustrated separated by a cell dielectric material 1263 extending into and out of the plane of the drawing sheet in second direction (D2) and along an axis of orientation of the horizontal access devices and horizontal storage nodes of the arrays of vertically stacked memory cells of the 3D memory. In FIG. 12C, the first dielectric material 1239 is shown separating the space between neighboring horizontally oriented access devices and horizontally oriented storage nodes.

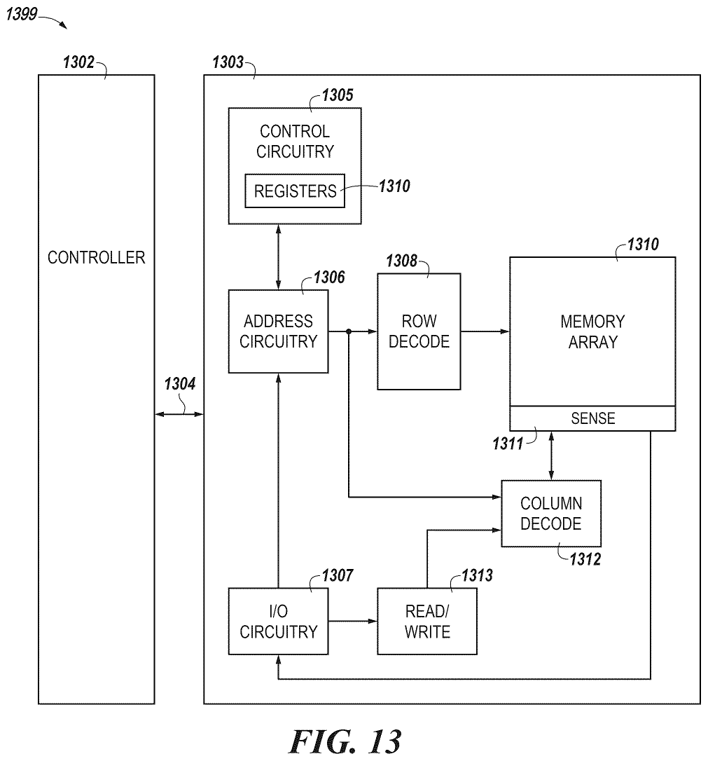

FIG. 13 is a block diagram of an apparatus in the form of a computing system 1399 including a memory device 1303 in accordance with a number of embodiments of the present disclosure. As used herein, a memory device 1303, a memory array 1310, and/or a host 1302, for example, might also be separately considered an “apparatus.” According to embodiments, the memory device 1303 may comprise at least one memory array 1310 with a memory cell formed having a digit line and body contact, according to the embodiments described herein.

In this example, system 1399 includes a host 1302 coupled to memory device 1303 via an interface 1304. The computing system 1399 can be a personal laptop computer, a desktop computer, a digital camera, a mobile telephone, a memory card reader, or an Internet-of-Things (IoT) enabled device, among various other types of systems. Host 1302 can include a number of processing resources (e.g., one or more processors, microprocessors, or some other type of controlling circuitry) capable of accessing memory 1303. The system 1399 can include separate integrated circuits, or both the host 1302 and the memory device 1303 can be on the same integrated circuit. For example, the host 1302 may be a system controller of a memory system comprising multiple memory devices 1303, with the system controller 1305 providing access to the respective memory devices 1303 by another processing resource such as a central processing unit (CPU).

In the example shown in FIG. 13, the host 1302 is responsible for executing an operating system (OS) and/or various applications (e.g., processes) that can be loaded thereto (e.g., from memory device 1303 via controller 1305). The OS and/or various applications can be loaded from the memory device 1303 by providing access commands from the host 1302 to the memory device 1303 to access the data comprising the OS and/or the various applications. The host 1302 can also access data utilized by the OS and/or various applications by providing access commands to the memory device 1303 to retrieve said data utilized in the execution of the OS and/or the various applications.

For clarity, the system 1399 has been simplified to focus on features with particular relevance to the present disclosure. The memory array 1310 can be a DRAM array comprising at least one memory cell having a digit line and body contact formed according to the techniques described herein. For example, the memory array 1310 can be an unshielded DL 4F2 array such as a 3D-DRAM memory array. The array 1310 can comprise memory cells arranged in rows coupled by word lines (which may be referred to herein as access lines or select lines) and columns coupled by digit lines (which may be referred to herein as sense lines or data lines). Although a single array 1310 is shown in FIG. 13, embodiments are not so limited. For instance, memory device 1303 may include a number of arrays 1310 (e.g., a number of banks of DRAM cells).

The memory device 1303 includes address circuitry 1306 to latch address signals provided over an interface 1304. The interface 1304 can include, for example, a physical interface employing a suitable protocol (e.g., a data bus, an address bus, and a command bus, or a combined data/address/command bus). Such protocol may be custom or proprietary, or the interface 1304 may employ a standardized protocol, such as Peripheral Component Interconnect Express (PCIe), Gen-Z, CCIX, or the like. Address signals are received and decoded by a row decoder 1308 and a column decoder 1312 to access the memory array 1310. Data can be read from memory array 1310 by sensing voltage and/or current changes on the sense lines using sensing circuitry 1311. The sensing circuitry 1311 can comprise, for example, sense amplifiers that can read and latch a page (e.g., row) of data from the memory array 1310. The I/O circuitry 1307 can be used for bi-directional data communication with the host 1302 over the interface 1304. The read/write circuitry 1313 is used to write data to the memory array 1310 or read data from the memory array 1310. As an example, the circuitry 1313 can comprise various drivers, latch circuitry, etc.

Control circuitry 1305 decodes signals provided by the host 1302. The signals can be commands provided by the host 1302. These signals can include chip enable signals, write enable signals, and address latch signals that are used to control operations performed on the memory array 1310, including data read operations, data write operations, and data erase operations. In various embodiments, the control circuitry 1305 is responsible for executing instructions from the host 1302. The control circuitry 1305 can comprise a state machine, a sequencer, and/or some other type of control circuitry, which may be implemented in the form of hardware, firmware, or software, or any combination of the three. In some examples, the host 1302 can be a controller external to the memory device 1303. For example, the host 1302 can be a memory controller which is coupled to a processing resource of a computing device.

The term semiconductor can refer to, for example, a material, a wafer, or a substrate, and includes any base semiconductor structure. “Semiconductor” is to be understood as including silicon-on-sapphire (SOS) technology, silicon-on-insulator (SOI) technology, thin-film-transistor (TFT) technology, doped and undoped semiconductors, epitaxial silicon supported by a base semiconductor structure, as well as other semiconductor structures. Furthermore, when reference is made to a semiconductor in the preceding description, previous process steps may have been utilized to form regions/junctions in the base semiconductor structure, and the term semiconductor can include the underlying materials containing such regions/junctions.

The figures herein follow a numbering convention in which the first digit or digits correspond to the drawing figure number and the remaining digits identify an element or component in the drawing. Similar (e.g., the same) elements or components between different figures may be identified by the use of similar digits. As will be appreciated, elements shown in the various embodiments herein can be added, exchanged, and/or eliminated so as to provide a number of additional embodiments of the present disclosure. In addition, as will be appreciated, the proportion and the relative scale of the elements provided in the figures are intended to illustrate the embodiments of the present disclosure and should not be taken in a limiting sense.

As used herein, “a number of” or a “quantity of” something can refer to one or more of such things. For example, a number of or a quantity of memory cells can refer to one or more memory cells. A “plurality” of something intends two or more. As used herein, multiple acts being performed concurrently refers to acts overlapping, at least in part, over a particular time period. As used herein, the term “coupled” may include electrically coupled, directly coupled, and/or directly connected with no intervening elements (e.g., by direct physical contact), indirectly coupled and/or connected with intervening elements, or wirelessly coupled. The term coupled may further include two or more elements that co-operate or interact with each other (e.g., as in a cause and effect relationship). An element coupled between two elements can be between the two elements and coupled to each of the two elements.

It should be recognized the term vertical accounts for variations from “exactly” vertical due to routine manufacturing, measuring, and/or assembly variations and that one of ordinary skill in the art would know what is meant by the term “perpendicular.” For example, the vertical can correspond to the z-direction. As used herein, when a particular element is “adjacent to” another element, the particular element can cover the other element, can be over the other element or lateral to the other element and/or can be in direct physical contact with the other element. Lateral to may refer to the horizontal direction (e.g., the y-direction or the x-direction) that may be perpendicular to the z-direction, for example.

Although specific embodiments have been illustrated and described herein, those of ordinary skill in the art will appreciate that an arrangement calculated to achieve the same results can be substituted for the specific embodiments shown. This disclosure is intended to cover adaptations or variations of various embodiments of the present disclosure. It is to be understood that the above description has been made in an illustrative fashion, and not a restrictive one. Combination of the above embodiments, and other embodiments not specifically described herein will be apparent to those of skill in the art upon reviewing the above description. The scope of the various embodiments of the present disclosure includes other applications in which the above structures and methods are used. Therefore, the scope of various embodiments of the present disclosure should be determined with reference to the appended claims, along with the full range of equivalents to which such claims are entitled.

What is claimed is:

1. A method for forming three dimensional (3D) arrays of vertically stacked memory cells, having horizontally oriented access devices and storage nodes, comprising:
forming a doped silicon (Si) material of a vertical stack on a substrate;
forming a first vertical opening through the vertical stack and into the substrate;
forming a second vertical opening through the vertical stack and into the substrate;
selectively removing the doped Si material to form a horizontal opening from the first vertical opening to the second vertical opening;
depositing a first material in the horizontal opening via the first vertical opening and the second vertical opening;
selectively removing the first material from the first vertical opening and the second vertical opening;
depositing a removable sacrificial material in the second vertical opening;
depositing a digit line liner in a vertical portion of the first vertical opening;
depositing an insulation material in the first vertical opening to fill a remaining portion of the first vertical opening;
selectively removing the sacrificial material in the second vertical opening;
selectively removing the first material in the horizontal opening and a first portion of the digit line liner via the second vertical opening;
depositing a second material on a second portion of the digit line liner and in the horizontal opening via the second vertical opening; and
selectively removing the second material from the second vertical opening.

2. The method of claim 1, further comprising selectively removing the doped Si material to form the horizontal opening from the first vertical opening to the second vertical opening via a wet etching process.

3. The method of claim 1, further comprising depositing the first material in the horizontal opening via the first vertical opening and the second vertical opening, wherein the first material is a metal or a metal oxide.

4. The method of claim 1, further comprising depositing the second material in the horizontal opening via the second vertical opening, wherein the second material is an oxide or a material with a dielectric constant greater than a dielectric constant of silicon dioxide.

5. The method of claim 1, further comprising selectively removing the first material in the horizontal opening and the first portion of the digit line liner via the second vertical opening, wherein the first portion of the digit line liner is on a sidewall of the doped Si material.

6. The method of claim 1, further comprising selectively removing the first material in the horizontal opening and the first portion of the digit line liner separates the second portion of the digit line liner from a third portion of the digit line liner, wherein the third portion of the digit line liner is on a sidewall of layers of silicon (Si) material included in the vertical stack.

7. The method of claim 1, further comprising depositing the digit line liner in the vertical portion of the first vertical opening and on the substrate.

8. The method of claim 7, further depositing the second material on the second portion of the digit line liner and in the horizontal opening via the second vertical opening, wherein the second portion of the digit line liner is on the substrate.

9. The method of claim 1, further comprising depositing the second material on the second portion of the digit line liner and in the horizontal opening via the second vertical opening, wherein the second material is an oxide or a material with a dielectric constant greater than a dielectric constant of silicon dioxide.

10. The method of claim 9, further comprising depositing the second material on the second portion of the digit line liner and in the horizontal opening via the second vertical opening to separate the second portion of the digit line liner from a third portion of the digit line liner.

11. The method of claim 10, further comprising isolating the vertical stack from the substrate by separating the second portion of the digit line liner from the third portion of the digit line liner.

12. A method for forming three dimensional (3D) arrays of vertically stacked memory cells, having horizontally oriented access devices and storage nodes, comprising:
forming an n-type doped silicon (N+ doped Si) material of a vertical stack on a substrate;
forming a first vertical opening through the vertical stack and into the substrate;
forming a second vertical opening through the vertical stack and into the substrate;
depositing a removable sacrificial material in the second vertical opening;
depositing a digit line liner in a vertical portion of the first vertical opening;
selectively removing the sacrificial material in the second vertical opening;
selectively removing the N+ doped Si material and a first portion of the digit line liner using a galvanic corrosion process to form a horizontal opening; and
depositing a dielectric material on a second portion of the digit line liner and in the horizontal opening via the second vertical opening.

13. The method of claim 12, further comprising selectively removing the N+ doped Si material and the first portion of the digit line liner without removing alternating layers of silicon germanium (SiGe) material and silicon (Si) material of the vertical stack.

14. The method of claim 12, further comprising selectively removing the N+ doped Si material and the first portion of the digit line liner using the galvanic corrosion process, wherein the galvanic corrosion process includes exposing the digit line liner and the N+ doped Si material, which are in ohmic contact, to an electrolyte.

15. The method of claim 14, further comprising exposing the digit line liner and the N+ doped Si material to the electrolyte, wherein the electrolyte is phosphoric acid (H3PO4).

16. The method of claim 14, further comprising exposing the digit line liner and the N+ doped Si material to the electrolyte via the first vertical opening and the second vertical opening.

17. A memory device, comprising:
a substrate; and
a three dimensional (3D) array of vertically stacked memory cells formed on the substrate, the vertically stacked memory cells having horizontally oriented access devices and storage nodes, comprising:
a first portion of a digit line liner formed on the 3D array of vertically stacked memory cells;
a second portion of the digit line liner formed on the substrate; and
a dielectric material having a portion formed between the first portion of the digit line liner and the second portion of the digit line liner and the substrate.

18. The memory device of claim 17, wherein a portion of the dielectric material is formed on the second portion of the digit line liner and the first portion of the digit line liner is formed on the dielectric material.

19. The memory device of claim 18, wherein the dielectric material separates the first portion of the digit line liner from the second portion of the digit line liner.

20. The memory device of claim 19, wherein the dielectric material isolates the 3D array of vertically stacked memory cells from the substrate by separating the first portion of the digit line liner from the second portion of the digit line liner.
